(19) United States
(12) Patent Application Publication
(10) Pub. No.: US 2022/0060150 A1
(43) Pub. Date: Feb. 24, 2022

(54) Cardiac Muscle-Cell-Based Coupled Oscillator Network for Collective Computing and Related Methods

(71) Applicants: University of Notre Dame du Lac, South Bend, IN (US); University of Virginia Patent Foundation, Charlottesville, VA (US)

(72) Inventors: Pinar Zorlutuna, South Bend, IN (US); Suman Datta, South Bend, IN (US); Jorge Gomez Mir, Bouth Bend, IN (US); Xiang Ren, South Bend, IN (US); Nikhil Shrikant Shukla, Charlottesville, VA (US); Jiaying Ji, South Bend, IN (US); Mohammad Khairul Bashar, Charlottesville, VA (US)

(21) Appl. No.: 17/407,604

(22) Filed: Aug. 20, 2021

Related U.S. Application Data
(60) Provisional application No. 63/068,547, filed on Aug. 21, 2020.

(51) Int. Cl. H03B 28/00; G06N 3/00

(52) U.S. Cl. CPC H03B 28/00; G06N 3/002

(57) ABSTRACT

A coupled bio-oscillating material is disclosed. The coupled bio-oscillating material comprises at least two cardiac muscle (CM) cell clusters and at least one cardiac fibroblast (CF) cell bridge on a substrate. The at least one CF cell bridge provides electrical conduction between the at least two CM cell clusters. The at least two CM cell clusters oscillate and synchronize at a unique phase ordering between the at least two CM cell clusters. The coupled bio-oscillating material can be used. The coupled bio-oscillating material can be used to create coupled bio-oscillator networks. A method of creating a coupled bio-oscillator network. The coupled bio-oscillator networks can be used for collective computing. A re-programmable bio-oscillatory network is also disclosed. The re-programmable bio-oscillatory network comprises a patterning layer, an enzyme channeling layer, and a pneumatic controlling layer.

### CLAIM OF PRIORITY

The present application claims priority to U.S. Provisional Application No. 63/068,547, filed Aug. 21, 2020, entitled Cardiac Muscle-Cell-Based Coupled Oscillator Network for Collective Coupling, the content of which is hereby incorporated herein by reference in its entirety.

### GOVERNMENT RIGHTS

This invention was made with government funds under Grant No. 1807551 awarded by the National Science Foundation, Division of Electrical, Communications and Cyber Systems. The U.S. Government has certain rights in this invention.

### BACKGROUND

Current rate of structured and unstructured data generation and the need for real-time data analytics can benefit from new computational approaches where computation proceeds in a massively parallel way while being scalable and energy efficient. Biological systems arising from interaction of living cells can provide such pathways for sustainable computing. Current designs that exploit biological components for biocomputing leverage the information processing units of the cells, such as DNA, gene, or protein circuitries and are inherently slow (e.g., hours to days speed), hence they are primarily being considered for archival storage of information.

### SUMMARY

Some embodiments of the present inventive concept provide a coupled bio-oscillating material. The coupled bio-oscillating material includes at least two cardiac muscle (CM) cell clusters and at least one cardiac fibroblast (CF) cell bridge on a substrate. The at least one CF cell bridge provides electrical conduction between the at least two CM cell clusters. The at least two CM cell clusters oscillate and synchronize at a unique phase ordering between the at least two CM cell clusters.

Some embodiments of the present inventive concept provide a coupled bio-oscillator network. The coupled bio-oscillator network includes at least two biological oscillators and at least one biological coupling element. The at least one biological coupling element connects the at least two biological oscillators. The at least two biological oscillators are synchronized with a unique phase ordering between the at least two biological oscillators.

Some embodiments of the present inventive concept provide a method of creating a coupled bio-oscillator network. The method includes preplating a mixture of cardiac muscle (CM) cells and cardiac fibroblast (CF) cells in culture; fabricating a biocompatible stencil for patterning the CM cells and the CF cells on a substrate; providing at least one biocompatible polymer blocker on the substrate to block at least one portion of the substrate; treating an unblocked portion of the substrate with a cell attachment agent to enable cell attachment on the substrate; coating the unblocked portion of the substrate with the mixture of CM cells and CF cells to seed at least two CM-CF cell clusters; and removing the at least one biocompatible polymer blocker to enable CF cells in the at least two CM-CF cell clusters to proliferate and fill at least one gap between the at least two CM-CF cell clusters and couple the at least two CM-CF cell clusters. The at least two CM-CF cell clusters are synchronized with a unique phase ordering between the at least two CM-CF cell clusters.

Some embodiments of the present inventive concept provide a re-programmable bio-oscillatory network. The re-programmable bio-oscillatory network includes a patterning layer. The patterning layer includes at least two biological oscillators and at least one biological coupling element. The at least one biological coupling element connects the at least two biological oscillators. The at least two biological oscillators are synchronized with a unique phase ordering between the at least two biological oscillators. The re-programmable bio-oscillatory network also includes an enzyme channeling layer. The enzyme channeling layer includes at least one enzyme channel on top of the at least one biological coupling element. The at least one enzyme channel guides an enzyme fluid to a specific point on top of each of the at least one biological coupling element. The re-programmable bio-oscillatory network further includes a pneumatic controlling layer. The pneumatic controlling layer includes at least one pneumatic channel crossing the at least one enzyme channel. The at least one pneumatic channel guides an air flow to selectively control a flow of enzyme fluid in each of the at least one enzyme channel.

Some embodiments of the present inventive concept provide a method of collective computing by a coupled bio-oscillator network. The method includes providing a graph representing a minimum vertex coloring problem. The method further includes providing a coupled bio-oscillator network mapped with the graph. The coupled bio-oscillator network includes a plurality of cardiac muscle (CM) cell clusters and a plurality of cardiac fibroblast (CF) cell bridges. The plurality of CM cell clusters is coupled by the plurality of CF cell bridges. Each of the plurality of CM cell clusters is mapped to a node of the graph and each of the plurality of CF cell bridges is mapped to an edge of the graph. The plurality of CM cell clusters oscillates and synchronizes at a steady-state sequence. The method further includes partitioning the plurality of CM cell clusters into independent sets by comparing the steady-state sequence to an adjacency matrix of the graph and assigning a unique color to each of the independent sets.

### BRIEF DESCRIPTION OF THE DRAWINGS

FIG. 1 are diagrams illustrating some example computationally hard problems that may be solved using coupled oscillator networks in accordance with some embodiments of the present inventive concept.

FIG. 2 are diagrams illustrating collective computing using bio-oscillators with comparison to solid-state semiconductor oscillators in accordance with some embodiments of the present inventive concept.

FIG. 3 is a diagram illustrating coupling and decoupling of two cardiac bio-oscillators within a network in accordance with some embodiments of the present inventive concept.

FIG. 4 are diagrams illustrating a programmable biocomputing logic using pre-patterned rat cardiac muscle (rCM) and rat cardiac fibroblast (rCF) in accordance with some embodiments of the present inventive concept.

FIG. 5 is a diagram illustrating a fabrication process of Polydimethylsiloxane (PDMS) blockers in accordance with some embodiments of the present inventive concept.

FIG. 6 is a diagram illustrating a bio-oscillator fabrication process with varying CF bridge lengths in accordance with some embodiments of the present inventive concept.

FIG. 7A is a diagram illustrating a cell pattern at the start beating time of a long-term recording of synchronization of a two-cluster oscillator on the microelectrode array (MEA) substrates in accordance with some embodiments of the present inventive concept.

FIG. 7B is a diagram illustrating a cell pattern at the end of a long-term recording of synchronization of a two-cluster oscillator on the MEA substrates in accordance with some embodiments of the present inventive concept.

FIG. 7C is an immunostaining image of two synchronized clusters after cell fixation in accordance with some embodiments of the present inventive concept.

FIG. 7D is a diagram illustrating examples of recorded wave forms using the MEA system at 1 hour, 8 hours, 20 hours, and 30 hours in accordance with some embodiments of the present inventive concept.

FIG. 7E are diagrams illustrating variations of frequencies in the two clusters during the 30-hour measurement in accordance with some embodiments of the present inventive concept.

FIG. 8 is an example illustrating a pseudocode for checking synchronization and extract phase difference between clusters in accordance with some embodiments of the present inventive concept.

FIG. 9A is a fluorescence image of the Calcium stained beating CMs in three-cluster oscillator on a commercial MEA in accordance with some embodiments of the present inventive concept.

FIG. 9B illustrates an example beating profile from video recordings for each of the three clusters in accordance with some embodiments of the present inventive concept.

FIG. 9C are diagrams illustrating a smoothed beating profile of each beating peak and an average beating profile for each of the three clusters in accordance with some embodiments of the present inventive concept.

FIG. 9D are diagrams illustrating the time gap between the beating start point to the peak, 50% decay and 90% decay in beating profiles for the three clusters in accordance with some embodiments of the present inventive concept.

FIG. 10 are a series of diagrams illustrating a fabrication process of a three-cluster oscillator with a Y-shape PDMS blocker in accordance with some embodiments of the present inventive concept.

FIG. 11 are a series of diagrams illustrating a frequency analysis of the three-cluster oscillator in accordance with some embodiments of the present inventive concept.

FIG. 12 are a series of diagrams illustrating a fabrication process of a four-cluster oscillator in accordance with some embodiments of the present inventive concept.

FIG. 13A is a diagram illustrating characteristics of two CM clusters separated by CF bridges of different lengths in accordance with some embodiments of the present inventive concept.

FIG. 13B is a close-up image of two CM clusters coupled with a CF bridge of 150 μm in accordance with some embodiments of the present inventive concept.

FIG. 13C is a diagram illustrating phase dependence on frequency and fibroblast length for the configurations presented in FIG. 13A in accordance with some embodiments of the present inventive concept.

FIG. 13D is a diagram illustrating an extraction of fibroblast RC coupling parameters in a Nyquist plot in accordance with some embodiments of the present inventive concept.

FIG. 13E is a diagram illustrating an equivalent circuit model of the cardiac cell in a two-cluster pattern in accordance with some embodiments of the present inventive concept.

FIG. 13F is a diagram illustrating phase dependence on frequencies with fibroblast length of 300 μm for the two-cluster pattern in accordance with some embodiments of the present inventive concept.

FIG. 14 is a graph illustrating the comparison between experimental and simulation results of phase dependence on frequency with different CF distances in accordance with some embodiments of the present inventive concept.

FIG. 15 is a graph illustrating the conductance domain and the capacitance domain in the phase-frequency space in accordance with some embodiments of the present inventive concept.

FIG. 16 is a diagram illustrating extraction of equivalent circuit parameters of the oscillators using impedance spectroscopy in accordance with some embodiments of the present inventive concept.

FIG. 17 are a series of diagrams illustrating effect of coupling parameters in accordance with some embodiments of the present inventive concept.

FIG. 18A is a diagram illustrating characteristics of three clusters of CM cells separated by CF bridges of 300 μm in accordance with some embodiments of the present inventive concept.

FIG. 18B is a diagram illustrating the phase evolutions of C2 and C3 compared to C1 over the entire experiment in accordance with some embodiments of the present inventive concept.

FIG. 18C is a polar plot illustrating the phase differences shown in FIG. 18B in accordance with some embodiments of the present inventive concept.

FIG. 18D are diagrams illustrating the simulation results of a 3-cluster oscillator and coloring solutions in accordance with some embodiments of the present inventive concept.

FIG. 19 are a series of diagrams illustrating a fabrication process of a 9-node bio-oscillator network in accordance with some embodiments of the present inventive concept.

FIG. 20 are a series of diagrams illustrating a fabrication process of a 64-node bio-oscillator network in accordance with some embodiments of the present inventive concept.

FIG. 21 are a series of diagrams illustrating a fabrication process of custom-made MEA in accordance with some embodiments of the present inventive concept.

FIG. 22 are a series of diagrams illustrating a process of rCM patterning on 3-node custom-designed MEA platform in accordance with some embodiments of the present inventive concept.

FIG. 23 are diagrams illustrating different patterns on a 4-node custom-made MEA in accordance with some embodiments of the present inventive concept.

FIG. 24 is a diagram illustrating measurements of electrical fields at different locations of the three-node bio-oscillator network in accordance with some embodiments of the present inventive concept.

FIG. 25 is a diagram illustrating beating profiles of the three CM clusters in accordance with some embodiments of the present inventive concept.

FIG. 26 are diagrams illustrating impedance measurements of bio-oscillator clusters on a custom-made MEA in accordance with some embodiments of the present inventive concept.

FIG. 27 are diagrams illustrating a fibroblast coupling scheme in accordance with some embodiments of the present inventive concept.

FIG. 28A are diagrams illustrating a process of video analysis for a 9-node network in accordance with some embodiments of the present inventive concept.

FIG. 28B are diagrams illustrating a comparison of phase difference extracted using MEA analysis and video analysis in accordance with some embodiments of the present inventive concept.

FIG. 28C is a diagram illustrating temporal waveforms of the 9 nodes extracted using video analysis in accordance with some embodiments of the present inventive concept.

FIG. 28D is a diagram illustrating Fourier transform of the waveforms of the oscillators in FIG. 28C in accordance with some embodiments of the present inventive concept.

FIG. 28E are diagrams illustrating a coloring solution for a 9-node graph based on phase extraction in accordance with some embodiments of the present inventive concept.

FIG. 29A is an image of a 64-node network in accordance with some embodiments of the present inventive concept.

FIG. 29B a diagram illustrating beating waveforms of the sub-network extracted from brightfield videos in accordance with some embodiments of the present inventive concept.

FIG. 29C is an image of the sub-network selected from the 64-node network in accordance with some embodiments of the present inventive concept.

FIG. 29D a diagram illustrating an optimal coloring graph of the 6-node sub-network in FIG. 29C in accordance with some embodiments of the present inventive concept.

FIG. 29E is a diagram illustrating a phase ordering of the 6-node sub-network in accordance with some embodiments of the present inventive concept.

FIG. 30A is a brightfield image of three rCM clusters on an MEA platform in accordance with some embodiments of the present inventive concept.

FIG. 30B is a diagram illustrating representative rCM electrical signals recorded by custom designed MEA in accordance with some embodiments of the present inventive concept.

FIG. 30C illustrates a polar histogram of the peak difference shown in FIG. 30B in accordance with some embodiments of the present inventive concept.

FIG. 30D is a Ca2+ fluorescent image of three rCM clusters in accordance with some embodiments of the present inventive concept.

FIG. 30E is a diagram illustrating an intensity plot of the peak difference of Ca²⁺ fluxes shown in fluorescent video in accordance with some embodiments of the present inventive concept.

FIG. 30F is a Nyquist plot of fibroblast bridge represented as an RC equivalent circuit with resistance of 200 kΩ and capacitance of 120 nF in accordance with some embodiments of the present inventive concept.

FIG. 31A is a diagram illustrating representative FP waveforms of iCM clusters recorded from custom designed MEA platform in accordance with some embodiments of the present inventive concept.

FIG. 31B is a diagram illustrating an average result of spike amplitude during a 40-minute recording in accordance with some embodiments of the present inventive concept.

FIG. 31C is a diagram illustrating an average result of beat period during a 40-minute recording in accordance with some embodiments of the present inventive concept.

FIG. 31D is a diagram illustrating an average result of field potential duration (FPD) during a 40-minute recording in accordance with some embodiments of the present inventive concept.

FIG. 31E is a diagram illustrating an average result of corrected field potential duration (cFPD) during a 40-minute recording in accordance with some embodiments of the present inventive concept.

FIG. 32 is a diagram illustrating beating frequencies of two bio-oscillators before coupling and after coupling in accordance with some embodiments of the present inventive concept.

FIG. 33 is a schematic diagram of a large array pixel selection using the specific row selection and the specific column selection in a semiconductor network.

FIG. 34A is a diagram illustrating a configuration of the CARBON device in accordance with some embodiments of the present inventive concept.

FIG. 34B is a diagram illustrating a bright view of the CARBON device in accordance with some embodiments of the present inventive concept.

FIG. 35 is a diagram illustrating coupling and de-coupling of the CARBON device in accordance with some embodiments of the present inventive concept.

FIG. 36 is the truth table of the CARBON device in accordance with some embodiments of the present inventive concept.

FIG. 37 are diagrams illustrating the COMSOL simulation of the decoupling abilities of the CARBON device in accordance with some embodiments of the present inventive concept.

FIG. 38A is a diagram illustrating a SPICE-compatible model for the cardiac cell and its subsequent integration into coupled oscillator networks in accordance with some embodiments of the present inventive concept.

FIG. 38B is a diagram illustrating the action potential generated using the circuit model in FIG. 38A in accordance with some embodiments of the present inventive concept.

FIG. 38C is a diagram illustrating the phase difference between two identical coupled cardiac cells as a function of fibroblast length in accordance with some embodiments of the present inventive concept.

FIG. 38D is a diagram illustrating the simulated phase-frequency relationship of two coupled cardiac cell oscillators and its comparison to experimental data in accordance with some embodiments of the present inventive concept.

FIG. 39 provides an illustrative example to demonstrate solving the minimum vertex coloring problem in a graph using the phase dynamics of CF-coupled cardiac cell oscillators in accordance with some embodiments of the present inventive concept.

FIG. 40 are diagrams illustrating solving a graph problem based on a bio-oscillator network in accordance with some embodiments of the present inventive concept.

FIG. 41 is a flowchart illustrating the post-processing scheme incorporated with the oscillator approach to improve the vertex coloring solution in accordance with some embodiments of the present inventive concept.

FIG. 42 is a table illustrating graph instances from the DIMACS database evaluated using the coupled oscillators without post-processing and with postprocessing in accordance with some embodiments of the present inventive concept.

FIG. 43 are a series of diagrams illustrating a Xyce platform for evaluating the dynamics of large graph networks with coupled oscillators in accordance with some embodiments of the present inventive concept.

FIG. 44A is a diagram illustrating a 21-node Halin graph network.

FIG. 44B is a diagram illustrating an oscillator generated coloring solution as a function of device-to-device variation in accordance with some embodiments of the present inventive concept.

FIG. 45 illustrates a data processing system in accordance with some embodiments of the present inventive concept.

### DETAILED DESCRIPTION OF EMBODIMENTS

The inventive concept now will be described more fully hereinafter with reference to the accompanying drawings, in which illustrative embodiments of the inventive concept are shown. This inventive concept may, however, be embodied in many different forms and should not be construed as limited to the embodiments set forth herein; rather, these embodiments are provided so that this disclosure will be thorough and complete, and will fully convey the scope of the inventive concept to those skilled in the art. Like numbers refer to like elements throughout. As used herein, the term “and/or” includes any and all combinations of one or more of the associated listed items.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

As will be appreciated by one of skill in the art, the inventive concept may be embodied as a method, data processing system, or computer program product. Accordingly, the present inventive concept may take the form of an entirely hardware embodiment or an embodiment combining software and hardware aspects all generally referred to herein as a “circuit” or “module.” Furthermore, the present inventive concept may take the form of a computer program product on a computer-usable storage medium having computer-usable program code embodied in the medium. Any suitable computer readable medium may be utilized including hard disks, CD-ROMs, optical storage devices, a transmission media such as those supporting the Internet or an intranet, or magnetic storage devices.

Computer program code for carrying out operations of the present inventive concept may be written in an object-oriented programming language such as Java®, Smalltalk or C++. However, the computer program code for carrying out operations of the present inventive concept may also be written in conventional procedural programming languages, such as the “C” programming language or in a visually oriented programming environment, such as VisualBasic.

The program code may execute entirely on the user's computer, partly on the user's computer, as a stand-alone software package, partly on the user's computer and partly on a remote computer or entirely on the remote computer. In the latter scenario, the remote computer may be connected to the user's computer through a local area network (LAN) or a wide area network (WAN), or the connection may be made to an external computer (for example, through the Internet using an Internet Service Provider).

The inventive concept is described in part below with reference to a flowchart illustration and/or block diagrams of methods, systems and computer program products according to embodiments of the inventive concept. It will be understood that each block of the illustrations, and combinations of blocks, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the block or blocks.

These computer program instructions may also be stored in a computer-readable memory that can direct a computer or other programmable data processing apparatus to function in a particular manner, such that the instructions stored in the computer-readable memory produce an article of manufacture including instruction means which implement the function/act specified in the block or blocks.

As used herein, “connect” and “couple” and their various forms in some embodiments of the present inventive concept refer to linking together electrically, mechanically, optically, and/or magnetically without departing from the scope of the present inventive concept.

Similarly, as used herein “biocompatible” refers to materials used in some embodiments of the present inventive concept being unharmful to living tissues. For instance, the substrate in some embodiments of the present inventive concept may be any biocompatible material, for example, plastic, glass, or silicon, and the cells can be grown, harvested and transferred to the substrate. Also for example, the blockers or patterning stencils in some embodiments of the present inventive concept may be made of any biocompatible polymers, for example but not limited to, PDMS.

“Cardiac Muscle (CM) cells” in some embodiments of the present inventive concept refer to cardiomyocytes (CMs), in comparison to fibroblasts, which is referred as Cardiac Fibroblast (CF) cells in some embodiments of the present inventive concept.

“Enzymes” in some embodiments of the present inventive concept refer to enzymes that breaks down proteins, such as pepsin, trypsin and chymotrypsin. For example, trypsin can be used to disconnect CF cells by breaking down the proteins connecting the CF cells.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the block or blocks.

As discussed in the background, current rate of structured and unstructured data generation and the need for real-time data analytics can benefit from new computational approaches where computation proceeds in a massively parallel way while being scalable and energy efficient. Biological systems arising from interaction of living cells can provide such pathways for sustainable computing. Current designs that exploit biological components for biocomputing leverage the information processing units of the cells, such as DNA, gene, or protein circuitries and are inherently slow (e.g., hours to days speed), hence they are primarily being considered for archival storage of information. On the other hand, electrically active living cells that could operate in the Megahertz regime and can be connected as networks to perform massively parallel tasks can transform biocomputing and lead to novel ways of high throughput information processing. Some embodiments of the present inventive concept provide coupled oscillator networks made of living cardiac muscle cells, or bio-oscillators, as collective computing components for solving computationally hard problems such as optimization, learning and inference tasks.

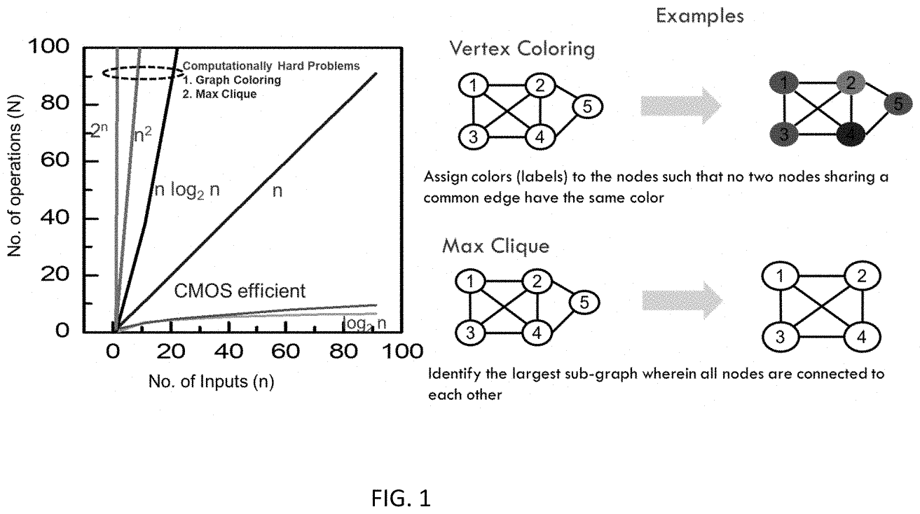

For example, FIG. 1 illustrates some computationally hard problems that may be solved in accordance with some embodiments of the present inventive concept. For example, vertex coloring is the task of assigning colors to the vertices of the graph such that no two vertices sharing the same edge have the same color, and it belongs to the class of combinatorial optimization problems. Also, for example, max clique is used to identify the largest sub-graph where all nodes are connected to each other.

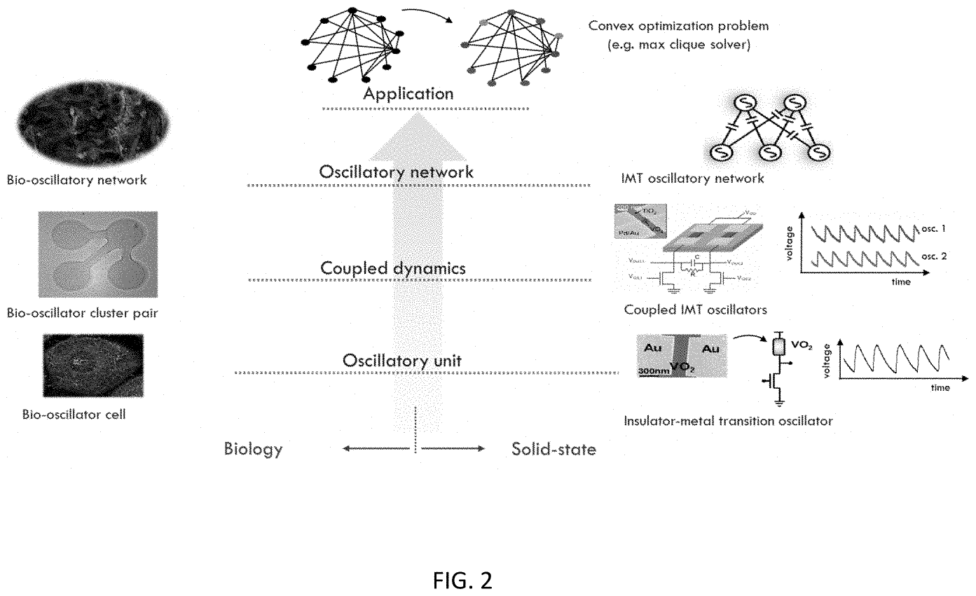

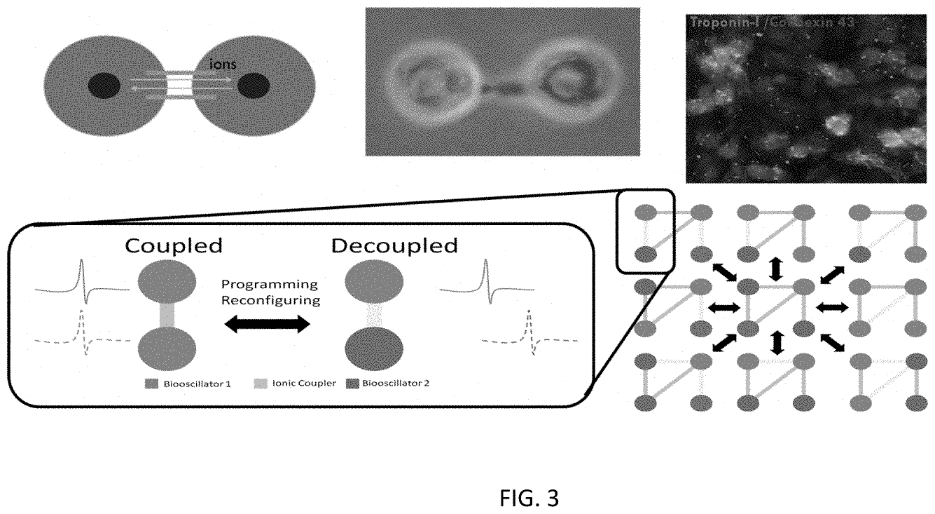

FIG. 2 illustrates collective computing using bio-oscillators with comparison to solid-state semiconductor oscillators. The coupling dynamics of two cardiac bio-oscillators fabricated using rat cardiac cells shows that they can be patterned to work similar to solid-state semiconductor oscillators. FIG. 3 illustrates coupling and decoupling of two cardiac bio-oscillators within a network. The two cardiac bio-oscillators can be programmed or reconfigured to couple together by an ionic coupler or decouple.

A 3-node network was fabricated to solve a graph coloring problem based on the coupling dynamics of these rat cardiac cells. A circuit compatible macro model was also developed and empirically validated with the cardiac cells acting as bio-oscillators and the fibroblast cells acting as coupling elements, to faithfully reproduce the synchronization dynamics of the network. Such a bio-oscillator network can be scaled up to hundreds of nodes and be used to solve computationally hard problems faster than traditional heuristics based Boolean algorithms. In some embodiments, three-dimensional (3D) bio-oscillator networks can be created to solve problems involving non-planar graphs.

Conventional complementary metal oxide semiconductor (CMOS) transistors working in the Boolean paradigm and guided by the Moore's law constitute the backbone of the current computational framework. However, certain classes of computational problems are fundamentally difficult to solve in the Boolean framework. Constrained optimization problems, such as vertex coloring of graphs, which is the task of assigning colors to the vertices of the graph such that no two vertices sharing the same edge have the same color, belong to the class of combinatorial optimization problems. Such computational tasks find extensive applications in many real-world problems such as fault diagnosis, scheduling, and resource allocation. However, these problems fundamentally exhibit non-deterministic polynomial-time hard (NP-hard) complexity. This implies that even the best algorithms end up searching the vast solution space in a greedy fashion for certain problem instances. Consequently, this manifests itself as an exponential increase in solution-time and computational resource with increasing size of the problem, when solved in the conventional Boolean computing framework. The inherently sequential approach of digital CMOS takes incremental discrete steps following the algorithm as the computation proceeds. In contrast, the rich spatiotemporal dynamics of the coupled oscillators can enable the system to search in a highly parallel fashion, the combinatorial optimization problems can be characterized in high dimensional configuration space, and the dynamics synchronization can drive the continuous-time trajectory to settle at or close to the global minima.

While such behavior has been observed in dynamical systems such as coupled oscillators and Hopfield Networks, this collective paradigm finds many natural analogs in biological systems such as decision-making mechanisms of neural networks, the swarm intelligence of bacterial colonies as well as the rhythmic beating of the cardiac muscle cells. An added advantage of these biological systems is that they require ultra-low energy, which is difficult to achieve in conventional solid-state devices and circuits. Therefore, some embodiments of the present inventive concept use the synchronized beating of living heart cells as a natural ultra-low energy (e.g., <nJ/bio-oscillator) biological hardware platform to implement a continuous-time dynamical system for solving computationally hard problems. The coupled relaxation oscillators exhibit a unique ordering of oscillator phases such that adjacent nodes (i.e., oscillators) belong to an independent set. In other words, the phase ordering produced by the oscillators is such that independent sets of the graph appear in a cyclic order. These dynamics arise from the equivalence between the eigenvalues of the adjacency matrix of the graph and the eigenvalues of the matrix describing the dynamics of the oscillators in state space. Consequently, this phase ordering can be partitioned into various independent sets and assigning a color to each set can approximate the near-optimal or optimal solution to the minimum vertex coloring problem.

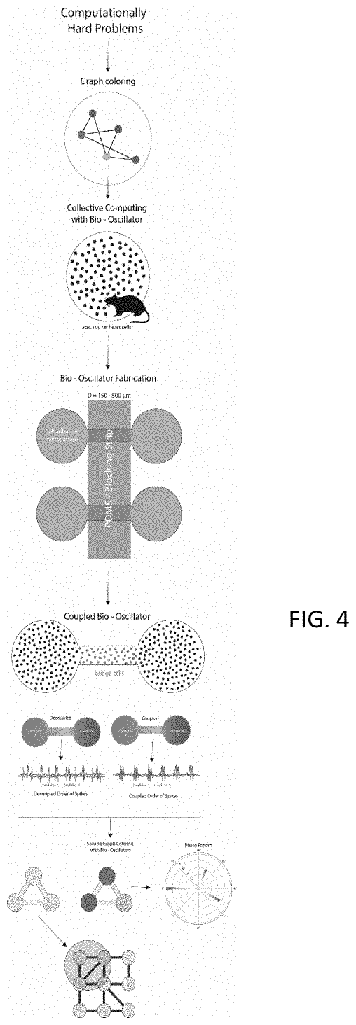

In some embodiments, as a model cell source, neonatal rat ventricular cardiac cells may be used to create the coupled bio-oscillators. The neonatal rate ventricular cardiac cells were isolated from two-day old Sprague-Dawley rat hearts following a previously established protocol in compliance with the IACUC guidelines and under an approved protocol from the University of Notre Dame. The isolated cell mixture of rat cardiac muscle (rCM) cells and rat cardiac fibroblast (rCF) cells were preplated for 2 hours in culture conditions to enrich the rCMs in the cell mixture. At the end of 2 hours preplating, the ratio of rCM to rCF was about 7:3. The rCM enriched cardiac cell mixture were collected from the culture flasks, suspended in the culture medium of Dulbecco's Modified Eagle Medium (DMEM) with 10% fetal bovine serum (FBS) and 1% penicillin, and used as the cell source throughout the study. FIG. 4 illustrates a programmable biocomputing logic using pre-patterned rCM and rCF in some embodiments of the present inventive concept.

Cardiac muscle (CM) cells are electrically active components that can initiate and relay electrical signals without loss. More interestingly, they spontaneously beat (i.e., oscillate) at a stable pace, and when coupled with each other, they synchronize to a locked, steady frequency. On the other hand, cardiac fibroblast (CF) cells in the heart are support cells that fill in the space between the CM cells and provide electrical pathways for ionic diffusion in between adjacent cells through the gap junctions that they make with the CM cells. The CF cells are not oscillatory (i.e., not beating), but they passively couple the beating CM cells. Some embodiments of the present inventive concept provide two kinds of computational elements, oscillators and coupling elements, to implement a coupled oscillator network. The beating CM cells function as oscillators, while the CF cells bridge in between and function as coupling elements, as illustrated in FIG. 4. The CF bridges between the CM clusters enable electrical conduction via ion exchange and provide an RC type coupling between the oscillatory elements. The distance between the CM clusters or the length of the CF bridge modulates the strength of coupling between the clusters.

Changes in the membrane potential of CMs can be recorded to study the continuous-time synchronization dynamics, for example, first as individual clusters and then as connected clusters through CF bridges, in real time. To create a well-defined network of connected cell clusters and monitor their spatially and temporally resolved dynamics of oscillation, the CMs and CFs can be patterned on glass substrates with an embedded microelectrode array (MEA). Polydimethylsiloxane (PDMS) blockers with varying width (e.g., 150 μm to 400 μm) and fixed height (120 μm) can be used to partially cover a cell adhesive protein micropattern to control the cell localization. It will be understood that this range of widths is provided for example only and that embodiments of the present inventive concept are not limited thereto. For examples, widths less than 150 μm and more than 400 μm may be provided without departing from the scope of the present inventive concept.

Although embodiments of the present inventive concept are discussed herein with respect to glass substrates, embodiments are not limited thereto. For example, the substrate may be any biocompatible material, for example, plastic or silicon, and the cells can be grown, harvested and transferred to the substrate.

PDMS Blocker Fabrication

It will be understood that although embodiments of the present inventive concept are discussed herein with respect to PDMS blockers, embodiments are not limited thereto. For example, any biocompatible polymer blocker may be used without departing from the scope of the present inventive concept.

In some embodiments using PDMS blockers, PDMS blockers can be fabricated with SU-83050 photoresist on silicon prime wafers using standard photolithography. FIG. 5 illustrates a fabrication process of PDMS blockers. The PDMS blockers were fabricated by soft lithography using a silicon wafer master with SU-83050 photoresist provided by Kayaku Advanced Materials, Inc. (formerly known as MicroChem). The SU-83050 was spin coated at 800 rpm with an acceleration of 300 r/s for 30 seconds to achieve a thickness of ˜140 μm. Then, the wafer was soft baked at 65° C. for 15 minutes followed by 60 minutes at 95° C. After the wafer with uncured SU-8 was cooled down to room temperature, the wafer was moved to a mask aligner (e.g., Karl Suss MA-3, SUSS MicroTech, Inc., Corona, Calif.) and covered with a negative photomask with blocker structures with desired dimensions (e.g., 150 to 500 μm in width). The exposure time was set to 17.8 seconds at 14 mW/cm², which provided a total dose of 250 mJ/cm² of i-line (365 nm) UV on the wafer. After the first UV exposure, the wafer was transferred to a hot plate for post exposure bake at 65° C. for 10 minutes and followed by 30 minutes at 95° C. Then the wafer was immersed in SU-8 developer for 10 minutes to remove the uncured SU-8. The wafer with the SU-8 pattern was cleaned by isopropanol and de-ionized (DI) water, then dried with a nitrogen gun. Tridecafluoro-1,1,2,2-tetrahydrooctyl-1-trichlorosilane (e.g., TFOCS by Fisher Scientific) was coated on the surface of the silicon wafer mold for the easy release of PDMS during the soft lithography. 0.3 mL of TFOCS was dropped on the surface of a petri-dish, with the mold placed next to the droplets. Then, the petri-dish was moved into a vacuum chamber for 1 hour. The TFOCS fully evaporated and formed a Teflon-like surface on the mold. After the mold was prepared, standard PDMS replica molding was conducted to fabricate PDMS blockers. PDMS pre-polymer (e.g., SYLGARD® 184 silicone elastomer, by Dow Corning, Midland, Mich.) and curing agent (e.g., SYLGARD® 184 silicone elastomer curing agent, by Dow Corning, Midland, Mich.) mixture with a weight ratio of 10:1 was poured on the TFOCS coated wafer mold. The mixture was then placed in a vacuum desiccator for 30 minutes to remove all of the air bubbles. The degassed PDMS mixture was poured onto the mold and placed in a 65° C. oven for 24 hours for the solidification of PDMS. The PDMS blockers were sterilized before manually attaching on to the MEA substrate.

The blockers were manually placed on the MEA substrate to block the parts of the substrate where the CM presence should be avoided. Then, 10% fibronectin diluted in phosphate buffered saline (PBS) was used to treat the unblocked parts of the MEA substrate in a 37° C. incubator for 30 minutes to enable CM attachment on the MEA substrate as separate clusters. Any natural or synthesized cell attachment agents can be used. The cell attachment agents can be protein molecules or peptide molecules diluted in a buffer solution. The culture medium was refreshed after majority of the CMs and CFs (7:3 mixture) were attached to the MEA substrate. The CMs within the CM-CF clusters start to beat after 1.5˜2 days of culture. The culturing time before beating depends on the cell type that is cultured. Then, the PDMS blocker was removed by a sterile tweezer, without interfering with the beating cell clusters. Once the blocker is removed in between the cell clusters, CFs in the CM-CF mixture will proliferate and migrate to fill in the gap, hence bridging the beating cell clusters. The cell membrane potential was continuously measured by MEA-2100 systems by Multichannel Systems with a sampling rate of 1 kHz up to 72 hours. This way, the membrane potential changes in the beating CMs were recorded before and after their coupling through an RC element, namely the CFs as the bridge cells, and the membrane potential data was analyzed for frequency and phase lag information for two and three clusters of bio-oscillators.

Two-Cluster Cell Patterning on MEA Substrates

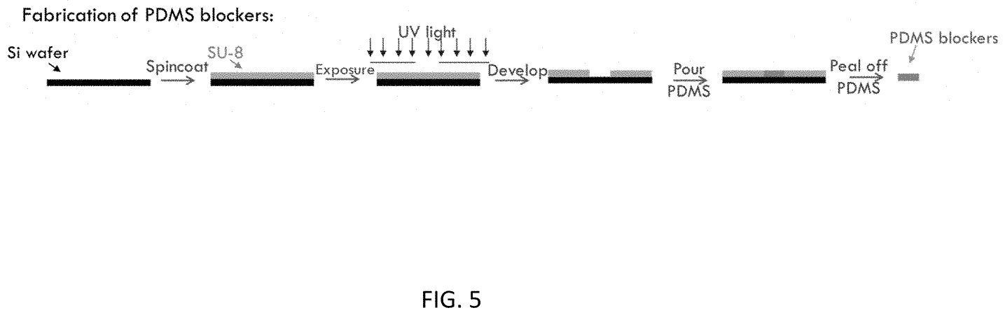

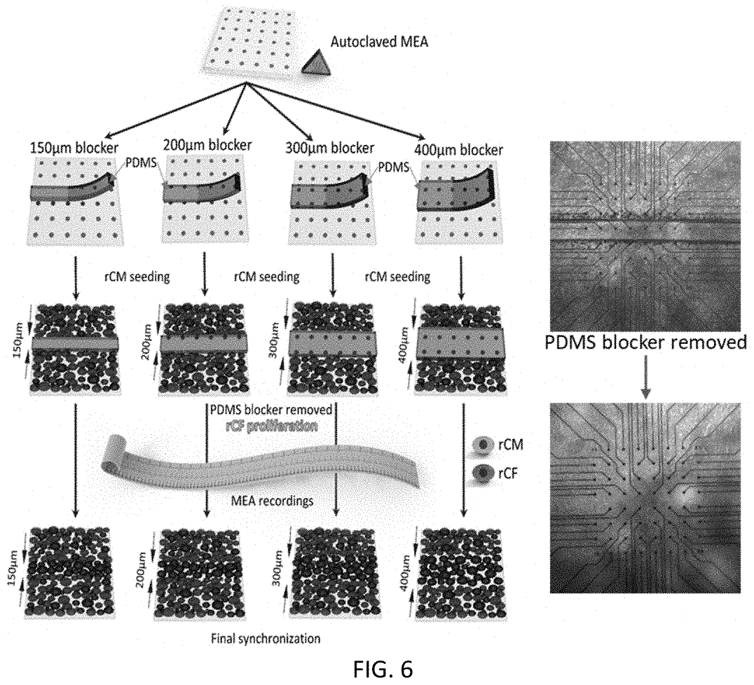

FIG. 6 illustrates a bio-oscillator fabrication process with varying CF bridge lengths in accordance with some embodiments of the present inventive concept. The commercial MEA (e.g., part #60PedotMEA200/30iR-AU, by Multichannel systems, Germany) surface was pre-cleaned by 1% enzyme-active detergent (e.g., Tergazyme, by Alconox Inc.) in DI water and autoclaved for sterilization. The rat CM adhesion requires fibronectin coating on these glass based MEA substrates to enhance cell attachment, while the CF cells can proliferate on the MEA substrate without need for any specific cell adhesion molecule. The PDMS blocker separating the two clusters was attached on the MEA substrate across the center of the electrode array. A thin piece of PDMS (e.g., 3 mm×3 mm×10 μm) was used to cover the reference electrode to avoid cell growth. The width of PDMS blockers was 150 μm, 200 μm, 300 μm, and 400 μm as illustrated in FIG. 6. Then, 200 μL of fibronectin with a concentration of 50 μg/mL in PBS was added on the MEA substrate with the PDMS blocker to coat the exposed sections of the MEA substrate. The MEA substrate was then transferred to a 37° C. incubator for 30 minutes. Following incubation, the fibronectin was washed away with PBS for three times. The CM cells were seeded with a density of 2×10⁵ cells/mL to reach 1×10⁵ cells/cm². Once the CM cells started to beat, the PDMS blocker was removed to let the CF cells to proliferate. The MEA substrate was then placed on MEA-2100 system to record the field potential of the clusters at 37° C. with 5% CO₂. A solid PDMS lid for MEA substrate was casted by replica molding on a 3D printed wax mold to minimize the evaporation.

After field potential recordings, immunostaining is used to visualize the CM and CF distribution on the MEA substrate. Cells were fixed with 4% paraformaldehyde (e.g., provided by Electron Microscopy Sciences) for 20 minutes at room temperature, followed by washing with PBS for 3 times. Cells were then permeabilized in Triton X-100 (e.g., 0.1%, by Sigma-Aldrich) for 30 minutes and then washed 5 times with PBS. Cells were blocked by goat serum (e.g., 5%, by Sigma-Aldrich) for 1 hour, and incubated with Vimentin (e.g., by Abcam, U.K.), or Troponin T (e.g., by Abcam, U.K.) primary antibody diluted (e.g., 1:150) in goat serum at 4° C. After 24 hours, cells were washed 5 times with PBS and then incubated with Alexa Fluor 594 (e.g., by Life-Technologies) and Alexa Fluor 488 (e.g., by Life-Technologies) secondary antibody diluted (e.g., 1:200) in goat serum at 4° C. for 4 hours. After incubation, cells were washed with PBS again and incubated with DAPI (e.g., 1:1000 for DAPI:PBS, by Sigma Aldrich) and then washed 5 times. Imaging was performed using a fluorescence microscope (e.g., Axio Observer.Z1, Zeiss, Germany, Hamatsu C11440 digital camera, Japan).

Field Potential Detection for a Two-Cluster Oscillator on MEA Substrate

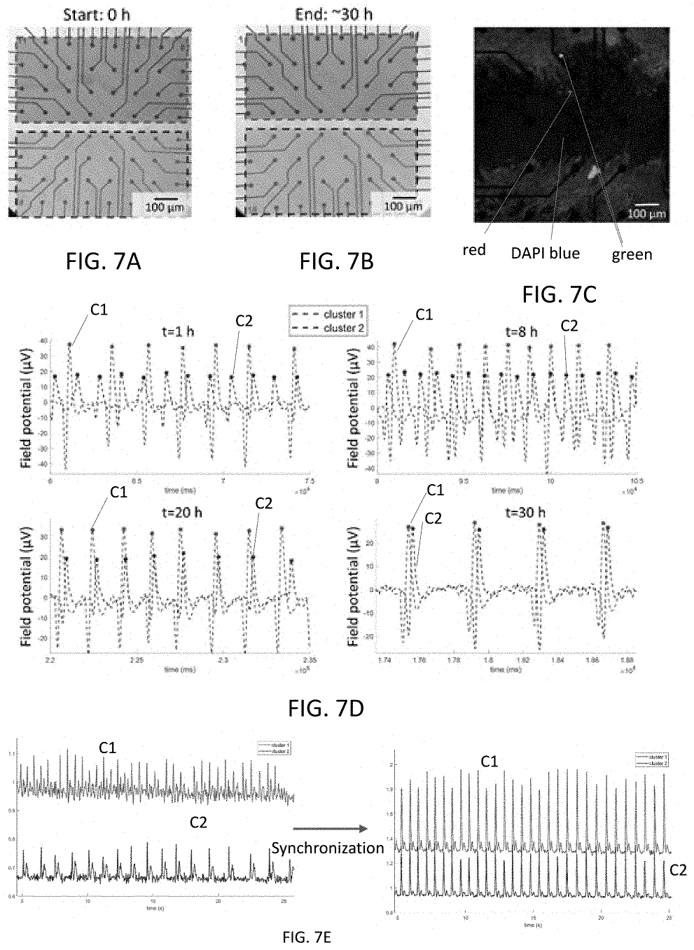

After the field potential recordings, data was analyzed using a custom-made code. First, the peaks were selected from the recorded waveforms of the beating CMs using Matlab® peak-selection function. Then, two representative electrodes were selected from each cell cluster (i.e., cluster 1 and cluster 2). FIGS. 7A and 7B are the bright field images of two clusters at the start (0 hour) and end (30 h) time of continuous recording of the synchronization. The CFs proliferated and connected the two clusters during the 30 hours that the recording was conducted. The synchronization progress was captured in between the two beating clusters. FIG. 7C shows an immunostaining image of the two synchronized clusters. The green color shows the CMs in two clusters. The DAPI blue color shows the nucleus of single cells. The CMs are not proliferating, while the CFs proliferate between the two clusters shown in red. Therefore, there are no green CMs between the clusters. FIG. 7D shows the voltage waves and the selected peaks before and after synchronization. The waveforms are filtered with a band pass filter to reduce the noise from baseline. It is noted that the noise still exists at the voltage ˜0V because of the band selection in the signal filter. All the noise was not filtered out to avoid missing any abnormal beating frequencies.

FIG. 7E illustrates variations of frequencies in cluster 1 and cluster 2 during the 30-hour measurement. The initial beating frequency of cluster 2 was faster than that of cluster 1. During the growth and proliferation of CFs, the beating frequencies starts to shift to higher values. After 10 hours, the CFs start to fill in the gap between clusters to form connections called gap junctions. The calcium exchange through the form gap junctions facilitates the synchronization. The two clusters reach the same frequency within 30 hours, depending on the length of the CF insert. As shown in FIG. 7D, the two waveforms of two clusters present a delay in time domain. This delay is caused by the electrical properties of the proliferated CFs between the two clusters. In some embodiments of the present inventive concept, this delay is utilized to build up phase difference in between multi-node oscillators.

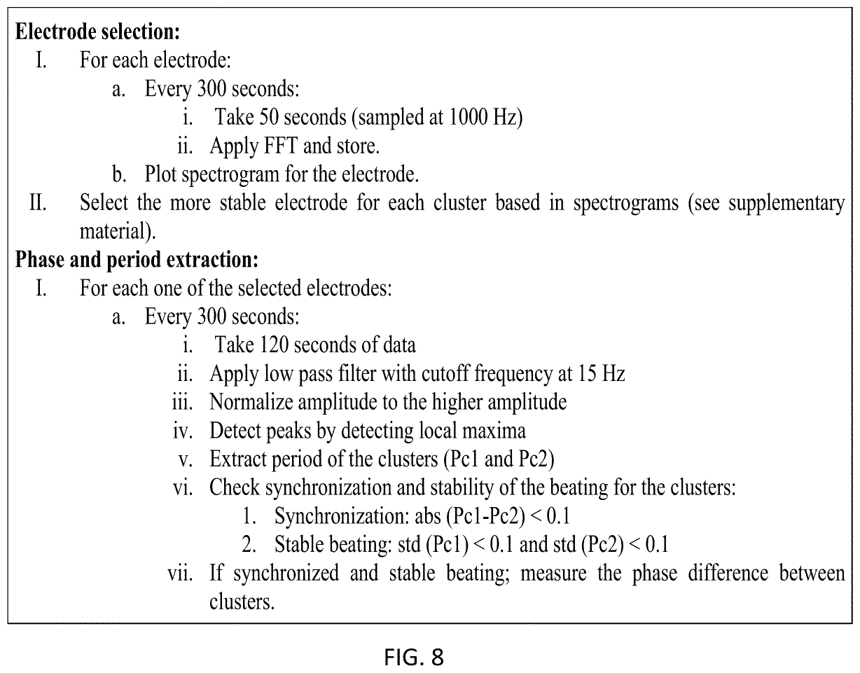

During the first 20 hours, the multiple frequencies gradually shift towards another frequency. The CMs with a CF length of 400 μm require >28 hours to reach a synchronized frequency. The synchronization dynamics extracted in time using peak detection is compared with the spectrogram of the electrodes. Even though the FFT does not present a single harmonic, all of the harmonics of the field potential are synchronized after 30 hours of CF proliferation. The methodology is briefly summarized in the pseudocode in FIG. 8.

Three-Cluster Oscillator on Commercial MEA

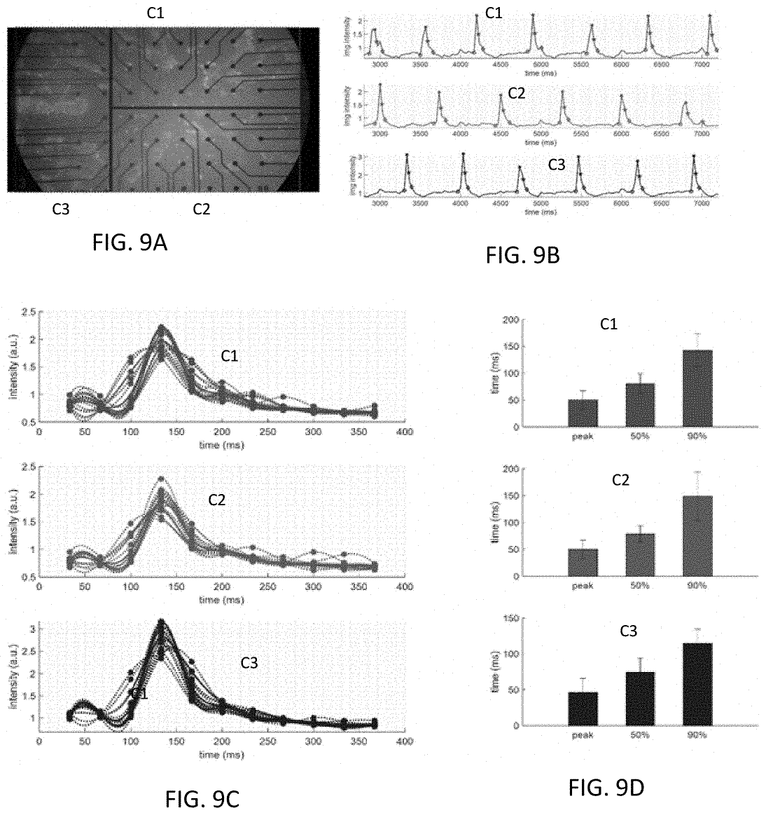

The three-cluster pattern can be fabricated similar to the two-cluster patterning strategy. In one embodiment, a T-shape PDMS blocker is used on the MEA substrate as illustrated in FIG. 9A. FIG. 9A is a fluorescence image of the Calcium stained beating CMs in three-cluster oscillator on a commercial MEA. The field potential recordings in FIG. 9B shows clear time lags between the cluster 1 (C1), 2 (C2), and 3 (C3). After the synchronization of the three clusters, the lags among the three clusters become stable and suitable for building a three-cluster oscillator. FIG. 9C illustrates a smoothed beating profile of each beating peak (dashed lines) and an average beating profile (solid line) for each of the three clusters. FIG. 9D illustrates the time gap between the beating start point to the peak, 50% decay and 90% decay in beating profiles for the three clusters. The beating profiles shown in FIGS. 9C and 9D indicate that all clusters were beating as expected of the rat CMs and were healthy upon the fabrication procedure they were exposed to.

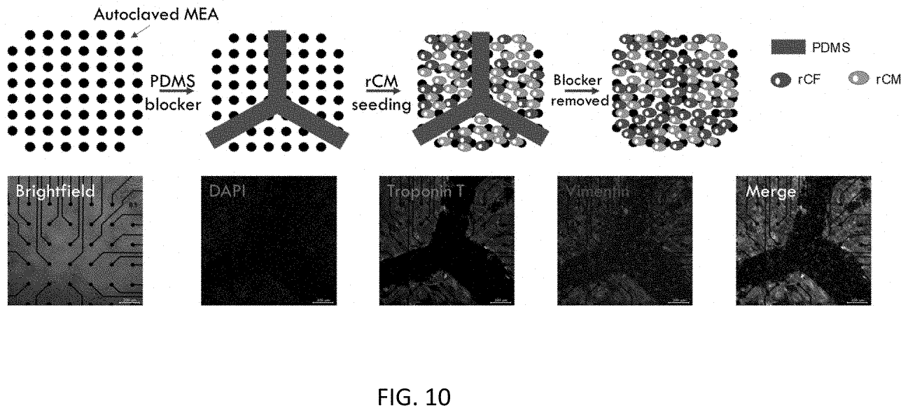

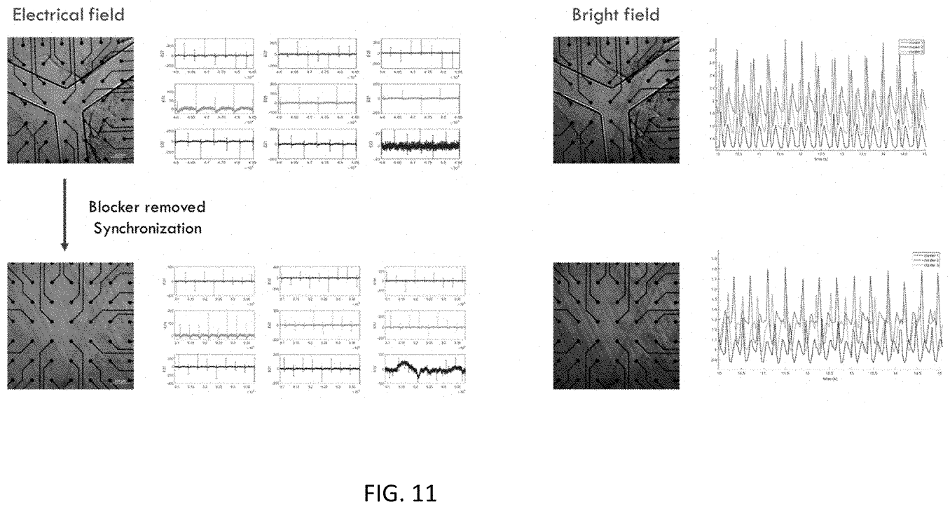

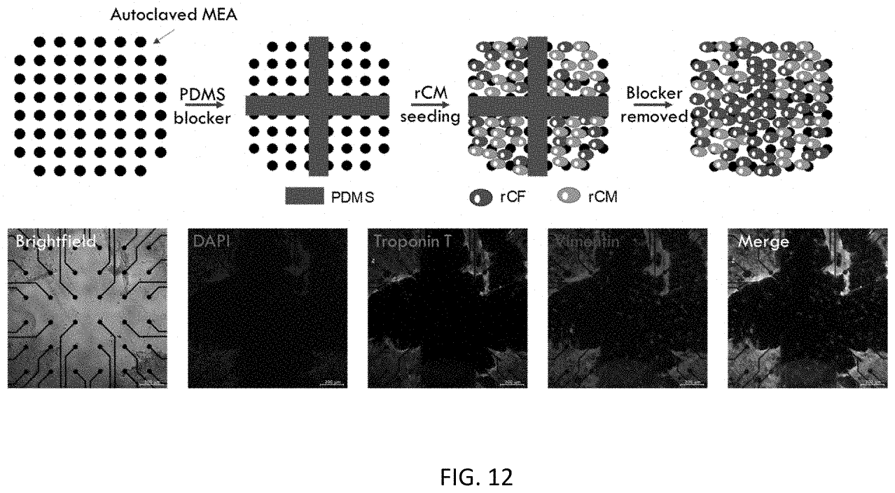

In another embodiment, a Y-shape PDMS blocker is used on the MEA substrate for fabricating a three-cluster oscillator as illustrated in FIG. 10. Immunostaining was also used to visualize the CM and CF distribution on the MEA substrate. FIG. 11 illustrates a frequency analysis of the three-cluster oscillator before and after synchronization. Similarly, a four-cluster oscillator can be fabricated. FIG. 12 illustrates a fabrication process of a four-cluster oscillator.

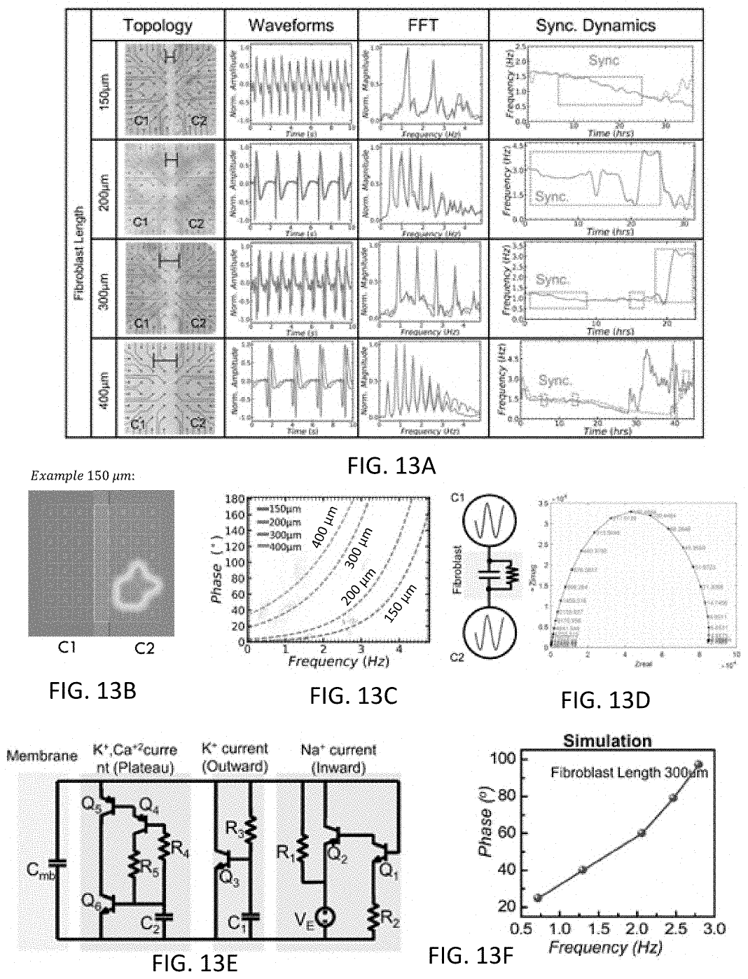

To study the impact of the coupling strength (i.e., length of the CF bridge) on the synchronization dynamics of beating clusters, the case of pairwise coupled clusters is first analyzed as illustrated in FIG. 13. Four different scenarios were defined by different fibroblast insert lengths: 150 μm, 200 μm, 300 μm and 400 μm. The first column of FIG. 13A shows the topologies of cell patterns used for each case. The clusters are shown as cluster 1 (C1) and cluster 2 (C2), and the coupling is shown in the middle. The action potential which is the potential difference across the membrane of the cell can be measured to monitor the synchronization of the clusters. However, the techniques for direct measurement, such as patch clamp technique, would disturb the cells and adversely affect the synchronization dynamics. For that reason, the extracellular electric potential known as field potential is measured to monitor the cell activity by using a commercial microelectrode array (MEA) that enables non-invasive and long-term measurements. From the measured field potential, the period and phase of the action potential which is the only read out that is needed for using this system for computing can be extracted. The second column of FIG. 13A shows the experimental field potential for each one of these topologies. Two methods can be used to extract the phase and period of oscillation for the bio-oscillators: Fourier transform and peak detection. The spectrogram for each electrode can be used to identify the regions in which the cells clusters are beating and synchronized, thereby the electrodes that will capture the representative cluster dynamics can be selected. The third column of FIG. 13A shows an example of synchronization of the two clusters in frequency domain as obtained from fast Fourier transform (FFT). The fourth column of FIG. 13A shows the evolution of the frequencies of both clusters, in which the synchronized regions are shown in boxes. The clusters can synchronize at different frequencies in a range of 0.3 to 4.5 Hz. Finally, using peak detection over the normalized waveform in the selected electrodes, the phase difference between the clusters for different frequencies can be extracted. For example, the pseudocode in FIG. 8 illustrates the procedure for checking synchronization and extracting phase difference between clusters. FIG. 13B is a close-up image of two CM clusters coupled with a CF bridge of 150 μm.

FIG. 13C is a plot of synchronization frequencies for four fibroblast widths. Although there is a variation in the extracted phase-frequency points, it can be concluded in a statistically significant fashion that: (i) the phase between the clusters is modulated by the fibroblast length; and (ii) the phase between the clusters is also modulated by the frequency. Synchronization dynamics of twin clusters is a function of gap width of fibroblast cells. The phase-frequency relation can be fit to an exponential equation as shown below:

Ph=αe^{βf} Eqn. (1)

where Ph is the phase, f is the frequency, α and β are fitting parameters. The fitting parameters for each fibroblast length are shown in Table 1.

TABLE 1
Extracted parameters for data fitting FIG. 13C.

| Fibroblast Length | α | β |
|---|---|---|
| 150 μm | 1 | 1 |
| 200 μm | 3 | 0.9 |
| 300 μm | 18 | 0.7 |
| 400 μm | 34 | 0.6 |

The impedance of the proliferated CF can be measured to model the electrical nature of coupling between the two oscillator clusters. As illustrated in FIG. 13D, the Nyquist plot (i.e., Cole-Cole plot) reveals that the CF presents itself as an RC filter between the two beating oscillatory clusters. The conductance per unit length and the ability to form gap junctions between the CF and CF, or between the CM and CF, can determine the maximum limit of the CF insert length between two clusters. The insert length can be from 1 μm to 1 mm or 1 cm. Selection of the insert length depends on cell types. However, insert sizes longer than 400 μm in length may result in unsynchronized clusters.

To simulate the oscillations in the action potential of the cardiac cell, an equivalent SPICE-compatible macro circuit model of the cardiac cell is implemented as shown in FIG. 13E. The model replicates using electronic components the three different currents arising from the sodium, potassium and calcium currents across the membrane. The circuit includes three branches with active elements to model the ionic Ca²⁺, K⁺, Na⁺ currents. The circuit parameters are adjusted to replicate the experimentally observed action potential of the oscillator. Tuning resistor R₁ and capacitor C₁ in FIG. 13E helps modulate the oscillation frequency of the cell between 0.3 Hz and 3 Hz. Oscillatory dynamics can be emulated using developed electrical circuit model as shown in FIG. 13E.

Further, the oscillators are coupled using a fibroblast layer which is modeled as a parallel combination of a resistor and capacitor. The behavior of the RC circuit is also calibrated to the experimentally measured impedance characteristics of a 300 μm CF bridge. The impedance of the RC circuit can be obtained using impedance spectroscopy; the plot in FIG. 13D reveals R_{CF}=200 kΩ and C_{CF}=120 nF. Using the above simulation framework, the phase-frequency characteristics for a pair of oscillators coupled with 300 μm fibroblasts can be generated. It can be observed that simulations in FIG. 13F exhibit a good qualitative match to the experimental trends observed in FIG. 13C.

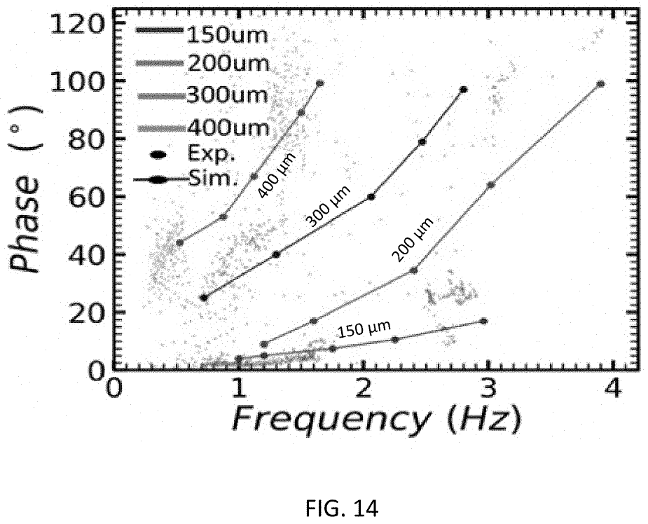

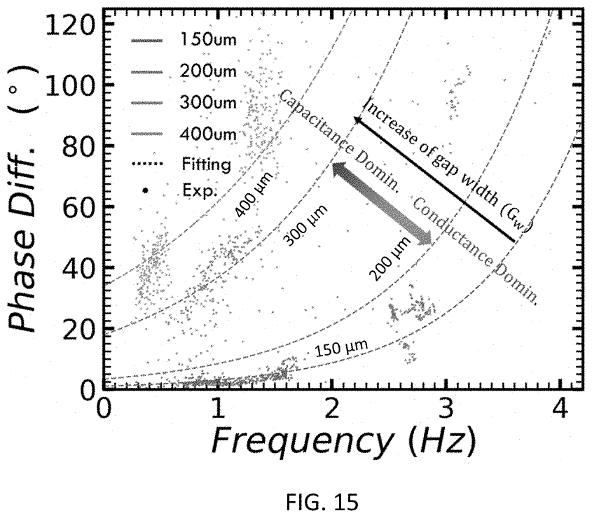

Going back to the phase-frequency relation, FIG. 14 illustrates the comparison between experimental and simulation results of phase dependence on frequency with different CF distances. Phase frequency behavior of the coupled oscillators can be qualitatively modeled. Gap width of fibroblast cells (G_{w}) (or Fibroblast Length (F_{L})) can modulate the phase-frequency relation between the clusters (in-phase versus anti-phase response). The fibroblast conductance (G_{f}), which is the inverse of the fibroblast resistance (R_{f}), is inversely proportional to F_{L}, as shown in Eqn. (2). The fibroblast capacitance (C_{f}) will not vary significantly by changing G_{w} (or F_{L}), as shown in Eqn. (3), thus the fibroblast time constant (R_{f} C_{f}) can change by varying the G_{w} (or F_{L}). It should be noted that in simulation, higher phase differences are observed either for very high resistive coupling or for pure capacitive coupling. FIG. 15 illustrates the conductance domain and the capacitance domain in the phase-frequency space.

$$\begin{matrix}{G}_{f} = \frac{1}{{R}_{f}} ∝ \frac{1}{{G}_{w}} & Eqn . ( 2 ) \\ {C}_{f} \approx Cte . & Eqn . ( 3 )\end{matrix}$$

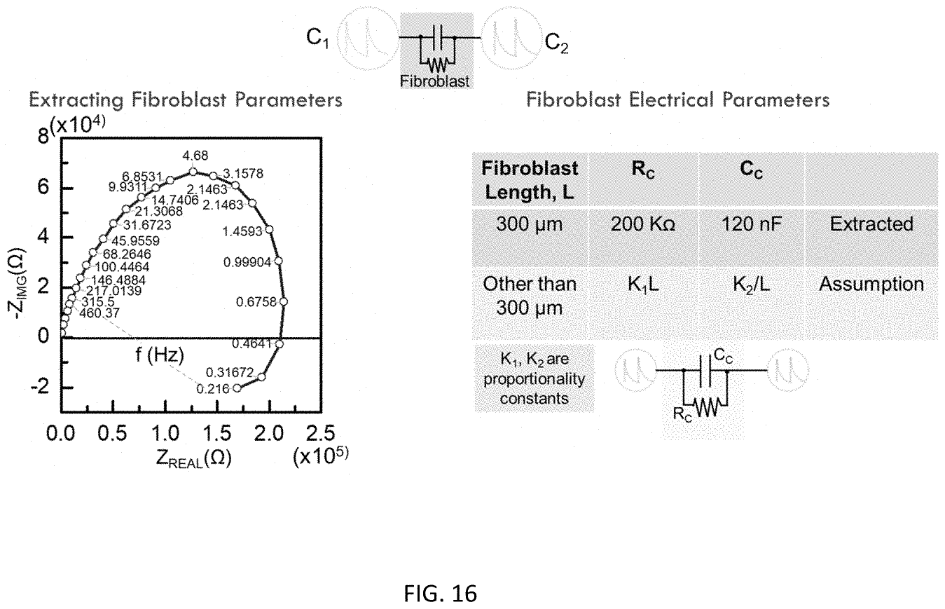

FIG. 16 illustrates extraction of equivalent circuit parameters of the oscillators using impedance spectroscopy. In the case of CF distance of 300 μm, Rc=200 kΩ, and Cc=120 nF. For distances of 150 μm, 200 μm, and 400 μm, Rc=K₁L and Cc=K₂/L are assumed.

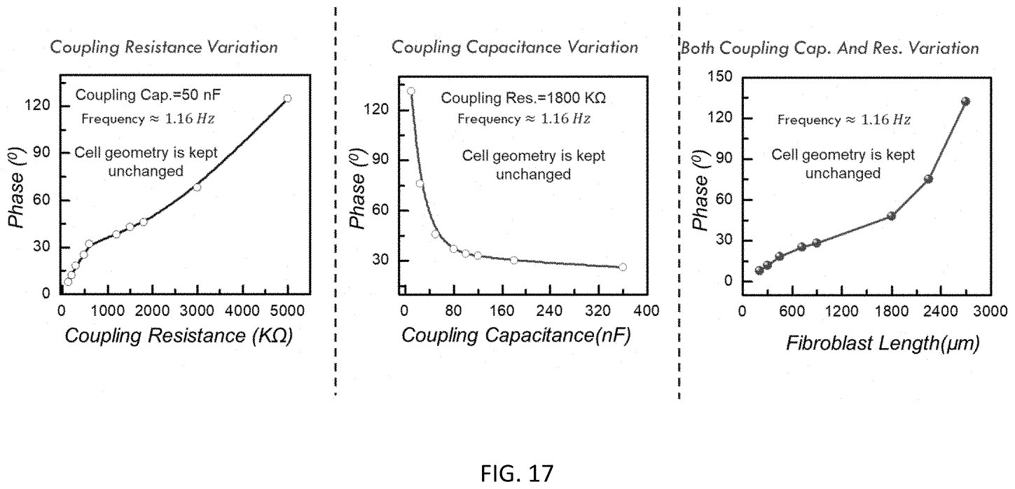

FIG. 17 illustrates effect of coupling parameters in accordance with some embodiments of the present inventive concept. When the coupling capacitance is set at 50 nF and the oscillation frequency is 1.16 Hz, the relation between the phase and the coupling resistance is illustrated. When the coupling resistance is set at 1800 kΩ and the oscillation frequency is 1.16 Hz, the relation between the phase and the coupling capacitance is illustrated. Again, when the oscillation frequency is 1.16 Hz, the relation between the phase and the length of the CF bridge (i.e., the combination of the coupling resistance and the coupling capacitance) is illustrated. It shows that phase changes nonlinearly with coupling parameters (i.e., fibroblast length) due to combined effect of coupling and internal circuit elements.

Spontaneous and continuous action potential generation (i.e., beating) of living cardiac cells makes them ideal candidates as biocomputational analog of oscillators. These bio-oscillators communicate through ion channels and synchronize to a steady frequency (i.e., couple). This communication is possible through gap junctions and intracellular pores which allow ion diffusion. After formed, the CM clusters initiate beating frequencies independently. The CM cells are non-dividing cells, which remain attached to the fibronectin coated regions of the MEA substrate. The CF cells, on the other hand, proliferate and occupy the regions previously covered by PDMS blockers. Once the CF cells proliferate and connect the two clusters together, the gap junctions between the CF and CM electrically couple the two and initiate calcium exchange between the CM clusters. The CM beating frequency starts to shift and both clusters synchronize to another frequency. This new frequency is not necessarily the frequency of either initial beating frequency, and it arises from the synchronization dynamics rather than a master-slave latch behavior.

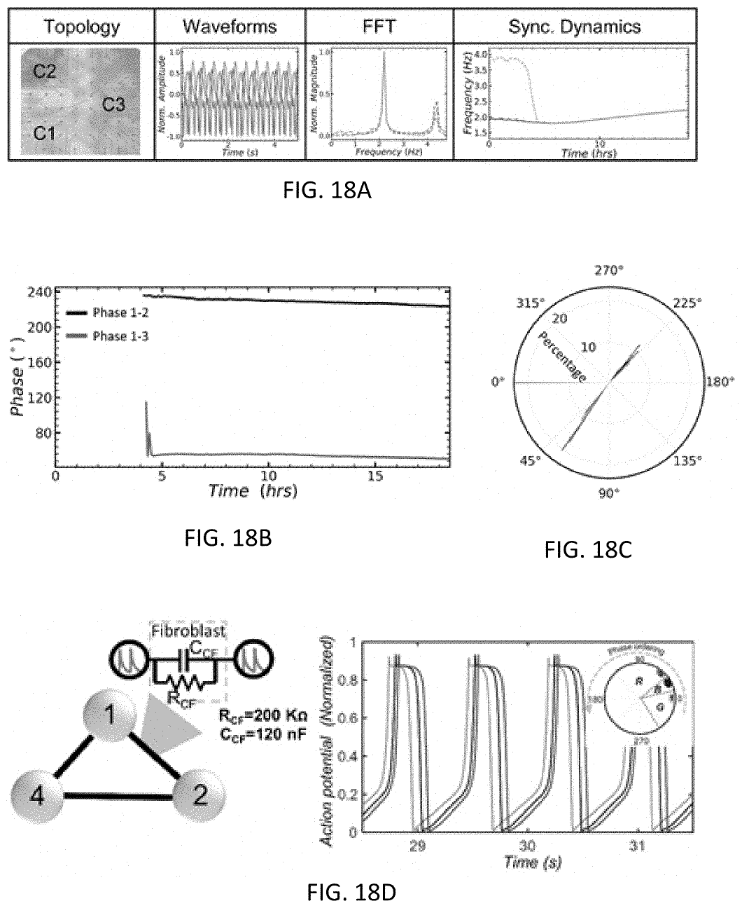

Based on the two-cluster oscillator results, 300 μm of fibroblast length is selected to implement a three-cluster network as illustrated FIG. 18. The first column of FIG. 18A demonstrates the topology of the three clusters built on the MEA. The clusters C1, C2, and C3, are presented as C1, C2, and C3, respectively. The second column in FIG. 18A presents the temporal waveform of the field potential of each cluster. The third column is the Fourier transform of a specific temporal snapshot of the three clusters in which they are synchronized. The fourth column shows the frequency alterations of each cluster during the long-term field potential monitoring. Synchronization dynamics of the three clusters in the fourth column shows out of phase response consistent with the dominance of capacitive coupling.

Cluster 1 C1 is used as the reference cluster to measure the phase differences. FIG. 18B shows the phase evolutions of C2 and C3 compared to C1 over the entire experiment. The same data is shown in a polar histogram in FIG. 18C with a resolution of 1 degree. The height of the histogram represents the percentage of the synchronization time that the phases are at a specific angle. The dispersion of the phases is narrow over 18 hours of the experiment. In this experiment the dimensions of the clusters are asymmetric, which reflects on the synchronization phases.

Although microelectrode-based field potential recording was used to precisely study the coupling dynamics in some embodiments, the optimized system discussed herein can use simple microscopy imaging to extract the phase and frequency information, such as Calcium transient imaging, for future applications where direct interface with traditional electronic devices is not needed. On one hand, using imaging as a read-out strategy could potentially increase the throughput as well as reduce the cost of device fabrication. On the other hand, ability to directly interphase with such traditional electronic devices might be an advantage and desired for applications where such read-outs would be valuable. In some embodiments of the present inventive concept, calcium imaging studies on the coupled oscillators were performed in order to show the functional integrity of the cells and as a proof of concept for an alternative high throughput read-out strategy in future studies.

Further, using the simulation framework described above, the synchronization dynamics of the fibroblast-coupled three-oscillator system is simulated as illustrated in FIG. 18D. The simulation shows a good qualitative match to the experimental data, revealing non-zero phase differences between each oscillator in the network. More importantly, the simulation and experiments show a phase ordering of the oscillators that can be leveraged for computing.

As described above, the coupling distance between the CM clusters, i.e. the length of the CF bridge, can be used to modulate the strength of coupling between the CM clusters. Two-cluster bio-oscillators and three-cluster bio-oscillators were fabricated. Some embodiments of the present inventive concept provide expanding bio-fabrication capabilities to create large scale bio-oscillator networks.

9-Node Network Fabrication

In some embodiments of the present inventive concept, neonatal rat ventricular cardiac cells were used as a model cell source to create coupled bio-oscillators. The neonatal rate ventricular cardiac cells were isolated from two-day old Sprague-Dawley rat hearts following a previously established protocol in compliance with the IACUC guidelines and under an approved protocol from the University of Notre Dame. The isolated cell mixture of rat CMs (rCMs) and rat CFs (rCFs) were preplated for 2 hours in culture conditions to enrich the CMs in the cell mixture. At the end of 2 hours preplating, the ratio of CM to CF was about 7:3. The CM enriched cardiac cell mixture were collected from the culture flasks and suspended in the culture medium of Dulbecco's Modified Eagle Medium (DMEM) with 10% fetal bovine serum (FBS) and 1% penicillin, and used as the cell source throughout the study.

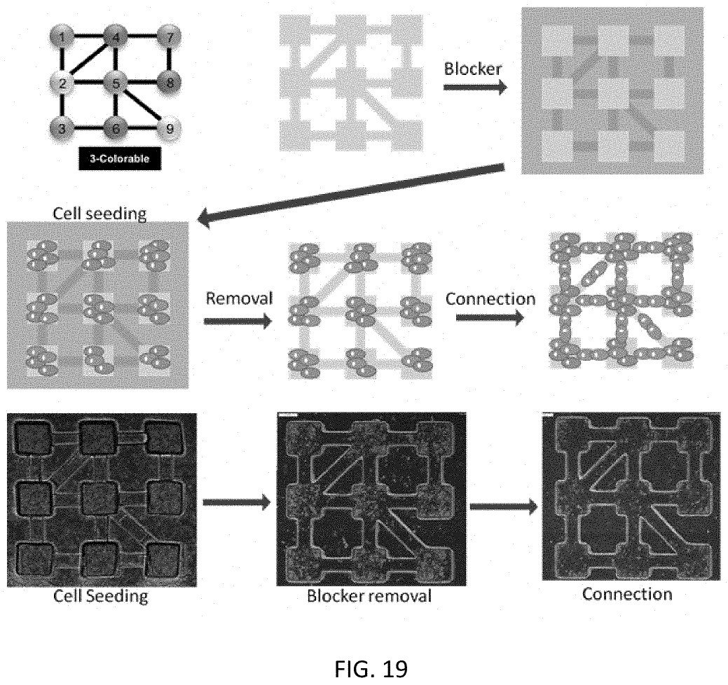

FIG. 19 illustrates a fabrication process of a 9-node bio-oscillator network. To create a well-defined network of connected cell clusters and monitor their spatial and temporally resolved dynamics of oscillation, the CMs and CFs are patterned on both plastic culturing plates and glass substrates. To control the cell localization, polydimethylsiloxane (PDMS) patterning stencils with a fixed height are used to define the CM nodes. The blockers used on the CF bridges are made by SU-8 photoresist (e.g., provided by MicroChem, Newton, Mass.). The PDMS stencils are fabricated by soft-lithography using a silicon wafer master that was fabricated with SU-83050 photoresist (e.g., provided by MicroChem, Newton, Mass.). Briefly, the SU-83050 was spin coated at 800 rpm with an acceleration of 300 r/s for 30 seconds to achieve a thickness of ˜140 μm. Then, the wafer was soft baked at 65° C. for 15 minutes followed by 60 minutes at 95° C. After the wafer with uncured SU-8 was cooled down to room temperature, the wafer was moved to a mask aligner (e.g., by Karl Suss MA-3, SUSS MicroTech, Inc., Corona, Calif.) and covered with a negative photomask. The exposure time was set to 17.8 seconds at 14 mW/cm², which provided a total dose of 250 mJ/cm² of i-line (e.g., 365 nm) UV on the wafer. After the first UV exposure, the wafer was transferred to a hot plate for post exposure bake at 65° C. for 10 minutes and followed by 30 minutes at 95° C. Then the wafer was immersed in SU-8 developer (e.g., provided by MicroChem, Newton, Mass.) for 10 minutes to remove the uncured SU-8. The wafer with the SU-8 pattern was cleaned by isopropanol and DI water, then dried with a nitrogen gun. Tridecafluoro-1,1,2,2-tetrahydrooctyl-1-trichlorosilane (e.g., TFOCS by Fisher Scientific) was coated on the surface of the silicon wafer mold for the easy release of PDMS. After the mold was prepared, standard PDMS replica molding was conducted to fabricate PDMS stencils. Both the PDMS stencils and SU-8 blockers were sterilized before manually attaching on to the culturing plates or glass substrate.

After fabrication, the SU-8 blockers were manually placed on the bridges of the PDMS stencil patterns to block the parts of the substrate where the CM presence should be avoided. Then, 10% fibronectin diluted in phosphate buffered saline (PBS) was used to treat the unblocked parts of the MEA substrate in a 37° C. incubator for 30 minutes to enable CM attachment on the MEA substrate as separate clusters. The culture medium was refreshed after majority of the CMs and CFs (7:3 mixture) were attached to the substrate. The CMs within the CM-CF clusters start to beat after 1.5˜2 days of cell culturing. Then, the blockers were carefully removed by a sterile tweezer, without interfering with the beating cell clusters. Once the blocker is removed in between the cell clusters, CFs in the CM-CF mixture will proliferate and migrate to fill in the gap, hence bridging the beating cell clusters.

64-Node Network Fabrication

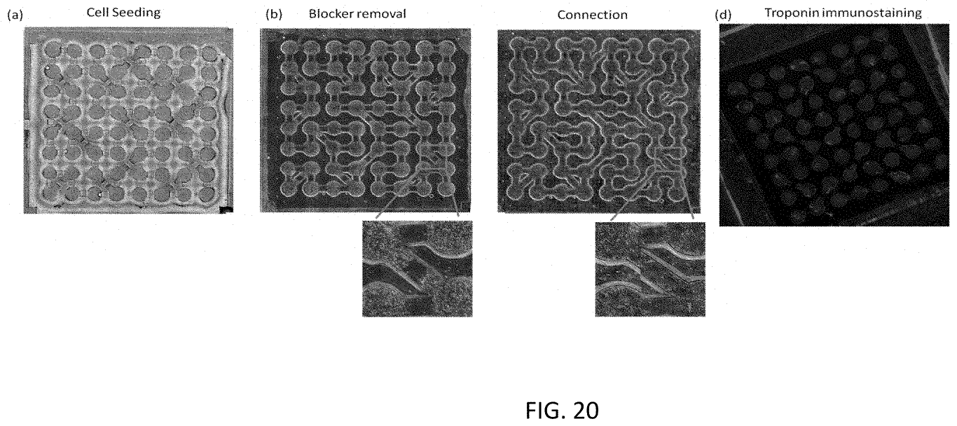

Similar to the 9-node patterning strategy, the 64-node network patterning was achieved by PDMS stencils and PDMS blockers on culture plates. FIG. 20 illustrates a fabrication process of a 64-node bio-oscillator network. After the removal of PDMS blockers, the CF proliferated to the bridges and form connections. FIG. 20 also shows the immunostaining of Troponin, the marker for CM, which was located within the nodes.

The 64-node bio-oscillatory network is a prototype network for solving vertex coloring problem in larger nodes. The different configurations among the nodes cover different scenarios of paired bio-oscillators.

Incorporating Microelectrode Arrays (MEA) in Multi-Node Networks

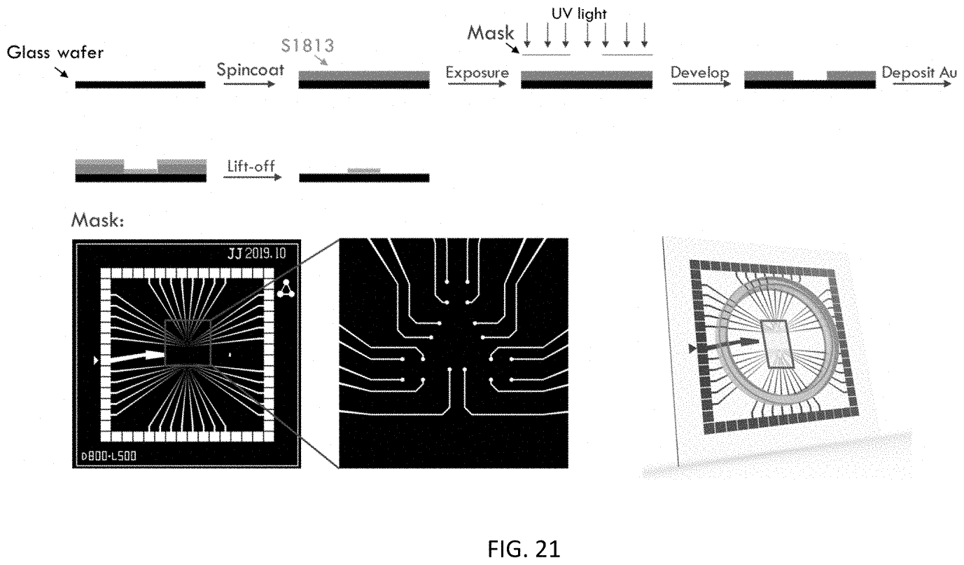

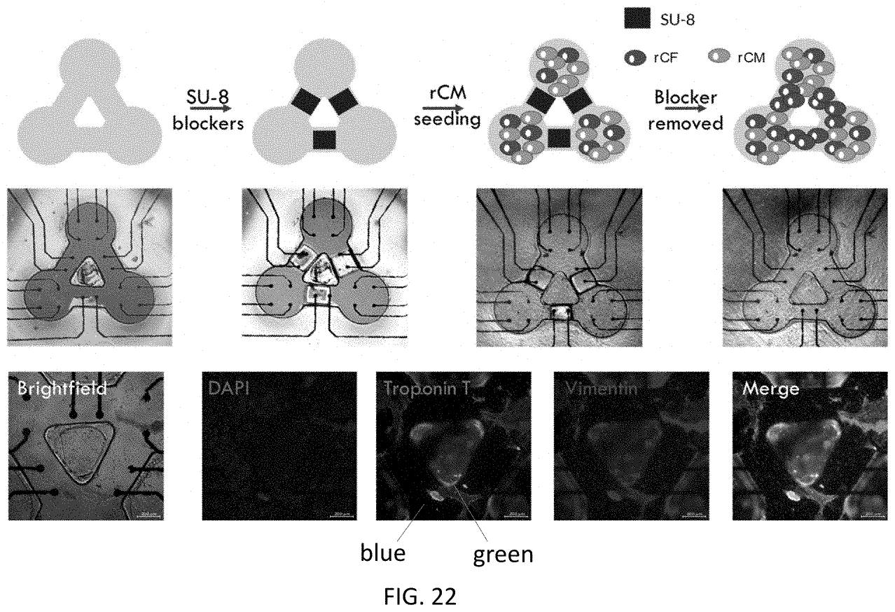

A customized MEA platform can be designed to match the micropattern of three interconnected clusters where electrodes are specifically positioned at each cluster and bridge. FIG. 21 illustrates a fabrication process of custom-made MEA.

Electrodes located at clusters can be used to detect the field potential from contracting rCMs, while the electrodes located at the bridges can be used to obtain propagation signals. Electrode pads around the MEA were designed to connect the detection system with 60 μm-diameter electrodes by 400 μm lines which shrink to 20 μm near the electrode. Electrode layout was fabricated on a glass wafer (e.g., 10 cm diameter), followed by the photoresist spin-coating, UV exposure, development, deposition of 20 nm-thick Cr and 100 nm-thick Au, and the lift-off process. Then, the glass wafer was cut off to 4.9 cm×4.9 cm to fit the MEA detection system. Finally, a PDMS-based ring was bonded with the MEA substrate to create the culture chamber for cells. By the standard lithography and metal deposition process, this methodology of customizing MEA can also be applied in more complex patterns.

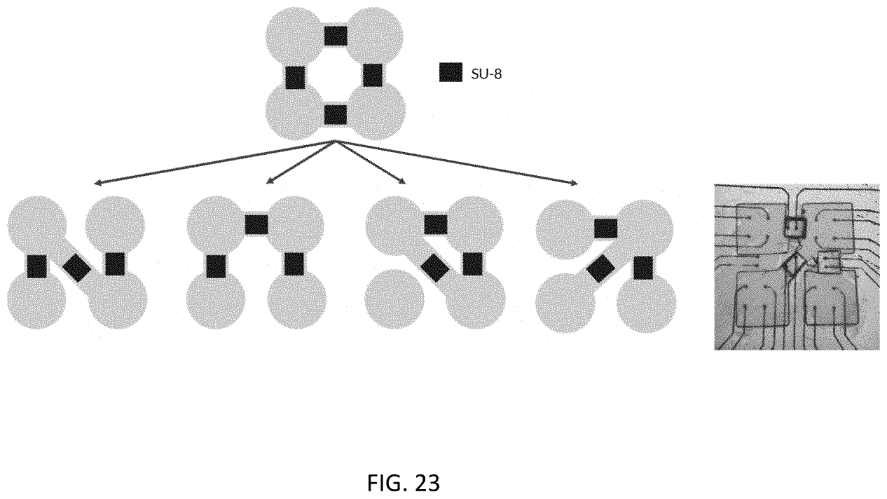

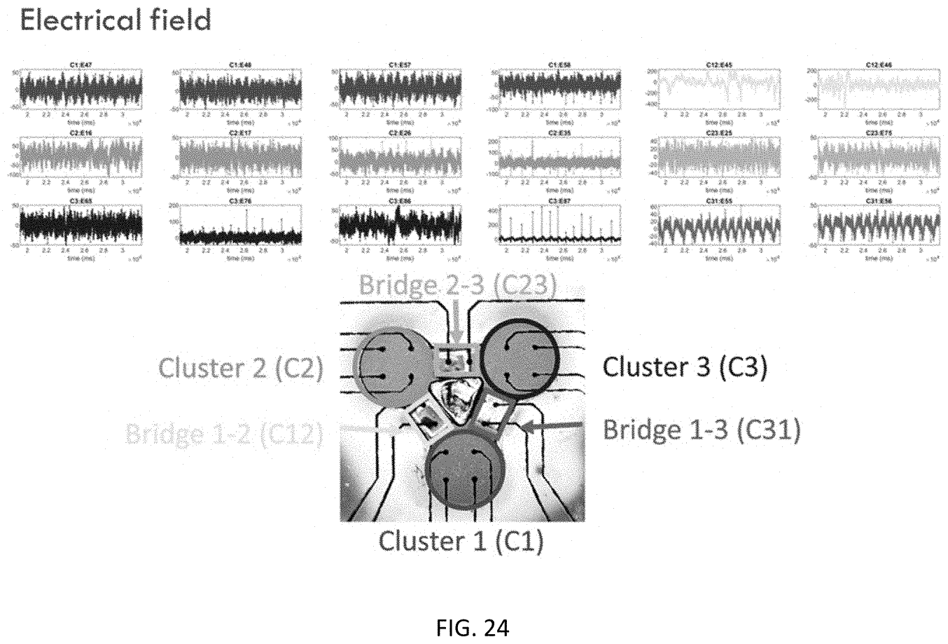

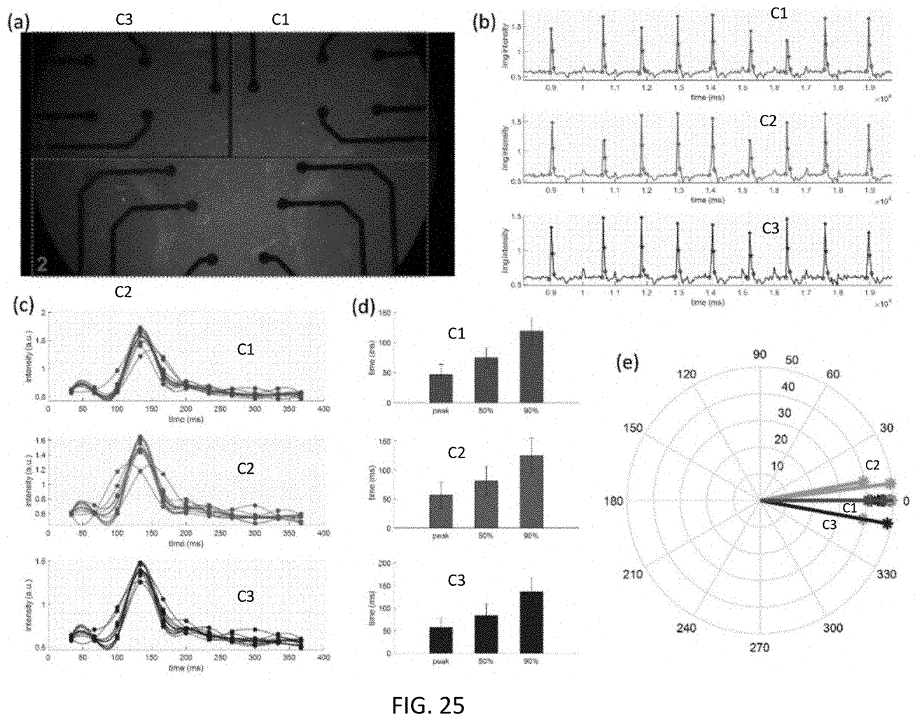

FIG. 22 illustrates a process of rCM patterning on 3-node custom-designed MEA platform. To achieve the CM-fibroblast network and guide the cardiac coupling pathway on the customized MEA, the PDMS-based topographic patterns were bonded with MEA substrate to define the cell areas, and mobile blockers were used to obstruct the three “bridges” between adjacent clusters. Then, neonatal rat cardiac cells, including rCMs and fibroblasts, were seeded into the MEA platform. Mammal CMs will lose their regeneration ability shortly after birth, while the fibroblasts can proliferate under proper culture conditions. Therefore, fibroblasts would grow in the empty “bridge” areas reserved by the blockers and connected adjacent rCM clusters. Immunofluorescence staining results were used to observe cell distribution and fibroblast growth in the MEA platform. FIG. 22 also illustrates immunostaining results of three separate rCM clusters connected by fibroblast. The nuclei and Troponin T (blue and green, respectively) can be seen clearly in the cluster areas, but no Troponin T signals in the “bridges,” verifying that blockers were successfully obstructed the connection pathway. The vimentin (red) is a fibroblast marker, which can be observed in both the bridges and the clusters, and the former indicated the fibroblast growth in the “bridges.” The immunostaining results verified that the cell micropatterning method in some embodiments of the present inventive concept is useful for defining cell distribution, and the usage of mobile blockers provides a controlled coupling pathway between rCM clusters, which can be applied to study the synchronization mechanism further. In the current version of the device, the three blockers are all removed together to obtain an interconnected pattern, but other patterns can also be achieved by adjusting the number of removed blockers or by controlling the removal sequence of the blockers. FIG. 23 illustrates different patterns on a 4-node custom-made MEA. FIG. 24 illustrates measurements of electrical fields at different locations of the three-node bio-oscillator network. FIG. 25 illustrates beating profiles of the three CM clusters.

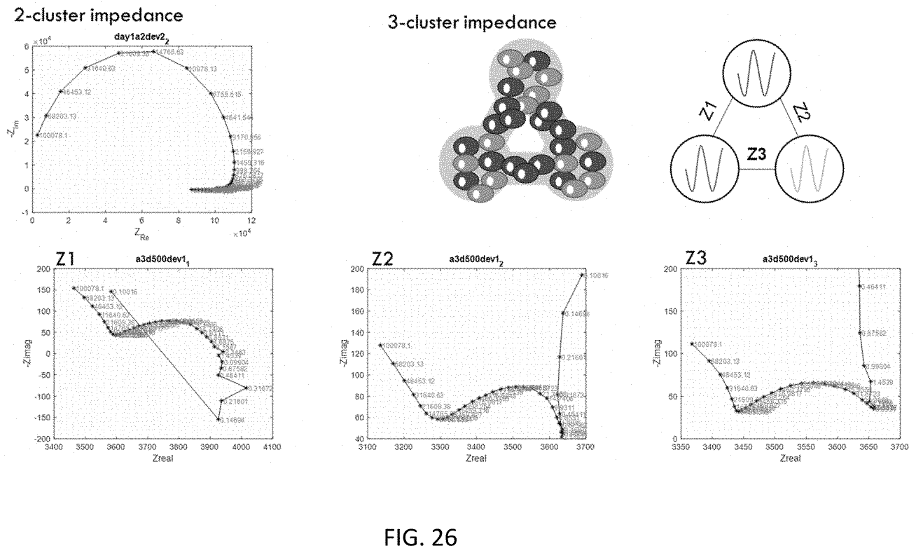

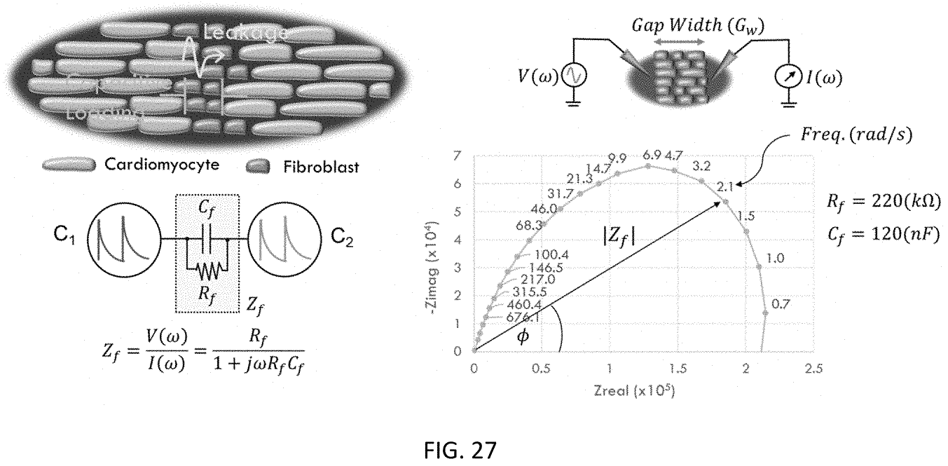

FIG. 26 illustrates impedance measurements of bio-oscillator clusters on a custom-made MEA. FIG. 27 illustrates a fibroblast coupling scheme. There are two mechanisms of electrical interaction between two clusters: resistive and capacitive. Impedance measurements provide quantitative estimates of electrical coupling elements.

Measurement of the Network Dynamics for Expanded Oscillatory Networks

MEA measurement can work well for small networks. However, to record and measure the network dynamics of large number of coupled bio-oscillators, such as those in the 9-node network and the 64-node network, instead of trying to fabricate electrodes that cover each node to record the field potential, brightfield video recordings are used to obtain the frequency and phase data. The imaging of an entire network is challenging due to large size of the field-of-view, but the entire network can be recorded using brightfield microscopy with an automated tile imaging stage and software to record the beating of large networks of bio-oscillators. Even though the calcium imaging of the cardiomyocytes (CMs) is more accurate for beating analysis, the cytotoxicity of the fluorescent imaging would affect the physiology of the cells for further growth and beating synchronization, and as such fluorescent microscopy was not pursued in some embodiments discussed herein.

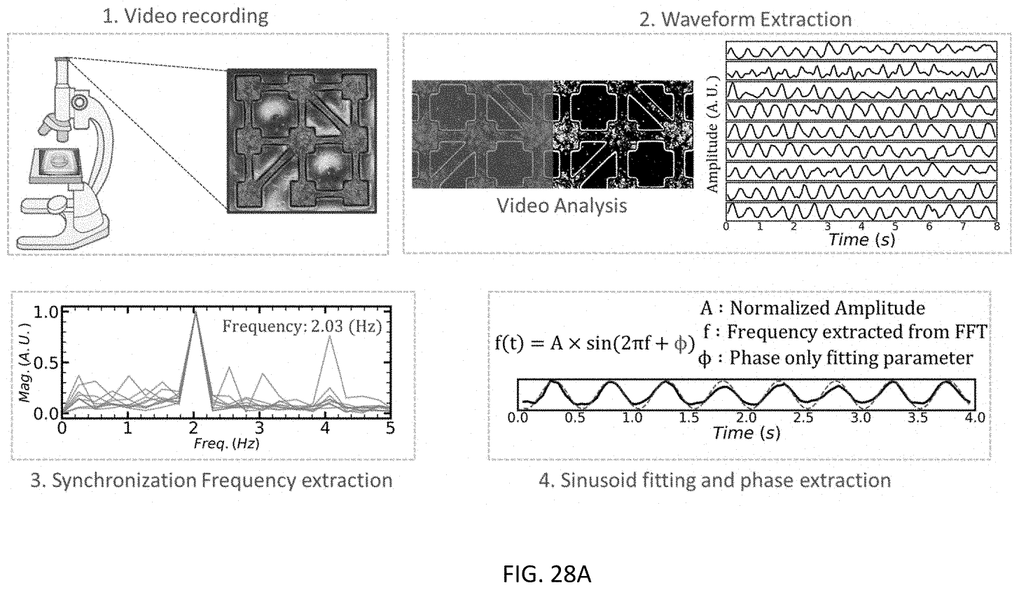

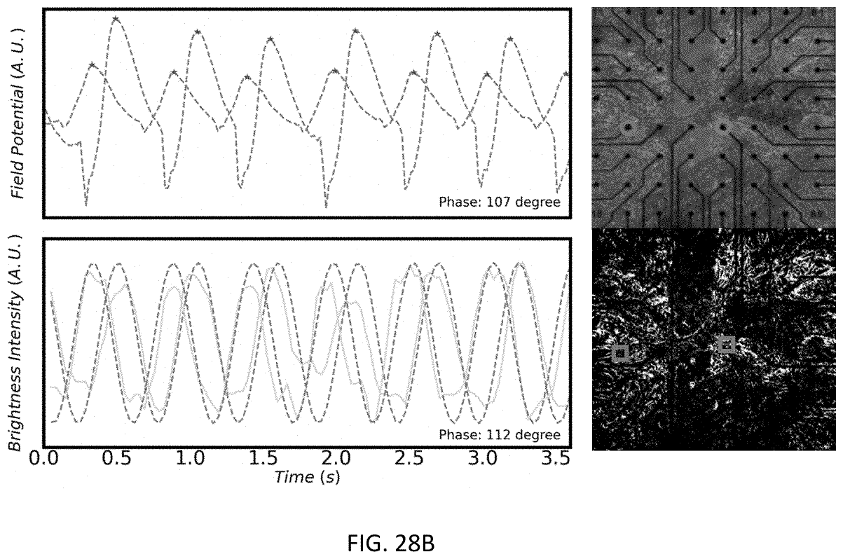

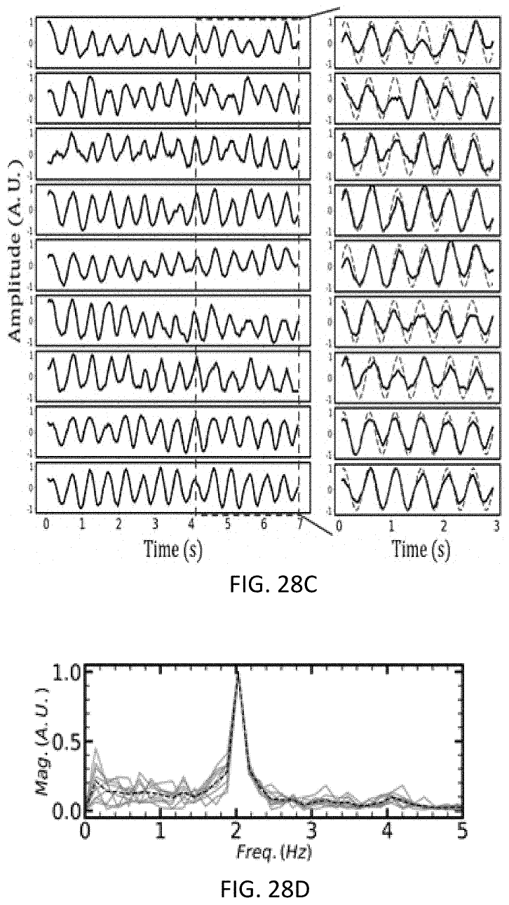

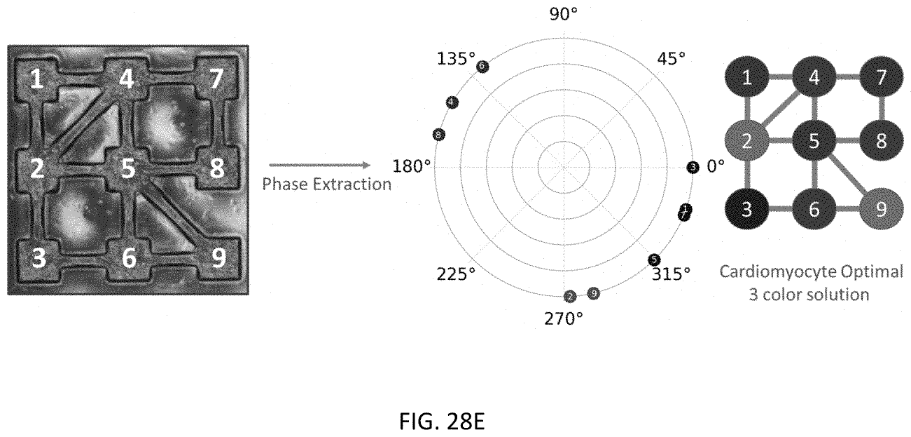

FIG. 28A shows a process of video analysis for a 9-node network. The 9-node network sample is put under a microscope for video recording. The topology of the 9-node network is displayed in FIG. 28A. Each node is a square with an area of 400×400 μm². The nodes are connected by 300 μm of fibroblast cell bridges. Using video analysis, the beating waveform of each node is extracted. The synchronization of the nodes can be analyzed by Fourier transform of the beating waveforms of the nodes. In this embodiment, the synchronization frequency is 2.03 Hz. A sinusoid waveform is then fit to the beating waveform of each oscillator node using the function shown in FIG. 28A. since the amplitude is normalized, and the synchronization frequency is obtained from Fourier transform, the only fitting parameter left is phase. To validate the phase extraction method described in FIG. 28A, the phase difference between two nodes extracted by MEA analysis is compared with the phase difference between the same two nodes extracted by video analysis is compared in FIG. 28B. It shows that the video analysis has an error of only 5 degrees compared to MEA analysis.

FIG. 28C shows the beating dynamics extracted using brightfield microscopy video analysis for the 9-node network. Because it is known that the beating frequency of the nodes will be in the order of the single digit Hz, a low-pass filter is applied to eliminate most of the noise. By taking the Fourier Transform of those waveforms, it demonstrates that all 9 nodes are synchronized as is shown in FIG. 28D in which each gray line corresponds to the Fourier Transform of one oscillator and the dashed black line is the average. By imposing a normalized amplitude and the synchronization frequency extracted from the Fourier analysis, a sinusoid is fitted by performing a least squares fitting. The phase difference between oscillators can be calculated with those sinusoids. The right-hand side of FIG. 28C shows the fitting between the sinusoid and the experimental data. The phase difference between the oscillators can be used to solve vertex coloring problems. FIG. 28E displays a coloring solution for a 9-node graph based on phase extraction. The 9-node network is used to represent a graph of a vertex coloring problem. The phase difference extracted above can be displayed in a polar plot. Group {1,3,5,7} can be colored with one color, group {2,9} can be colored with a different color, and group {4,6,8} can be colored with a color different from the first two colors.

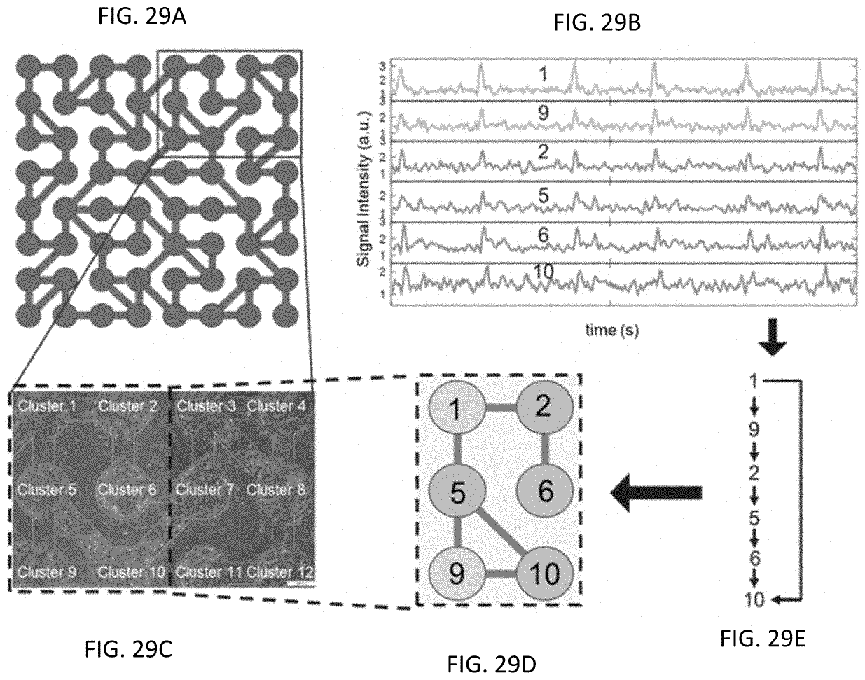

A topology of the 64-node network is shown in FIG. 29A. Each node is a circle with a diameter of 800 μm. The nodes are connected by 300 μm of fibroblast cell bridges as well. The overall dimension of the network reaches ˜1 cm². FIG. 29C shows a sub-network of 12-node selected from the 64-node network. The scale bar in the bright field image is 200 μm. Same as the 9-node network, the beating waveforms of the sub-network are extracted from the brightfield videos, as shown in FIG. 29B. In FIG. 29E, the resulting sequence of the 6-node sub-network represents a unique ordering of the phases: . . . 1, 9, 2, 5, 6, 10 . . . . Subsequently, this ordering can be partitioned into 3 independent sets {1, 9}, {2, 5} and {6, 10} using a polynomial operation. Assigning each set with a different color implies the optimal coloring graph of the 6-node sub-network, as illustrated in FIG. 29D.

Extracellular Recording of Synchronized Rat CM-Fibroblast Network

As a parallel approach to the brightfield video analysis, electrodes can also be incorporated in larger scale networks to detect the field potential directly. A customized microelectrode array (MEA) was fabricated for a 3-node bio-oscillator network and the MEA measurements were incorporated with the commercial detection and recording equipment, for example, MEA-2100 system (by Multichannel Systems, Germany). The customized MEA platform enables the specific detection at the location of interest and allows the investigation of the synchronization dynamics in a 3-node prototype by long-term electrical monitoring.

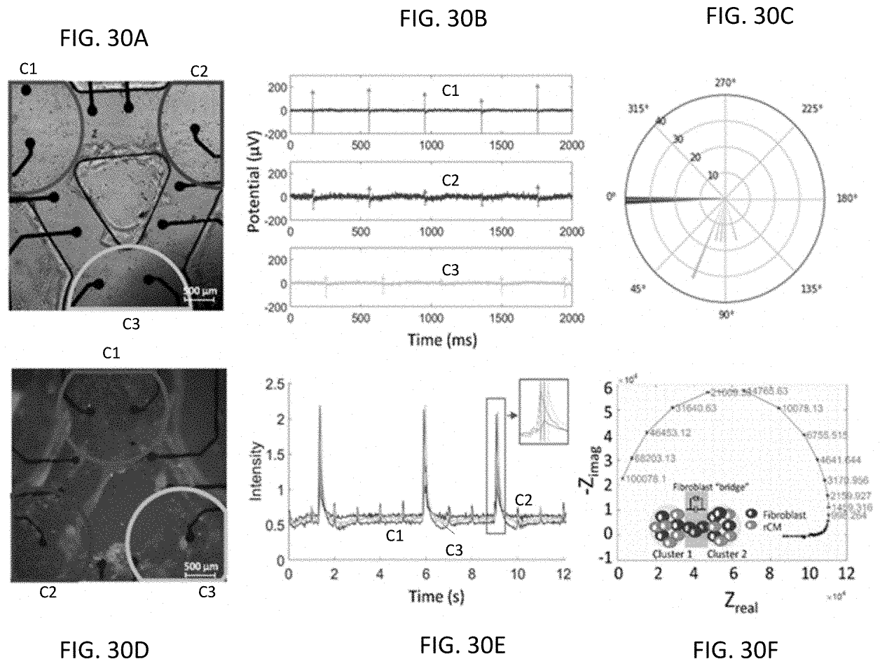

The neonatal rat cardiac cells are patterned into three individual clusters on the MEA platform, as shown in FIG. 30A. Every two adjacent cluster is connected by 300 μm of fibroblast bridges. When the synchronized contraction of the three rCM clusters was observed from the microscope, the MEA platform was placed in the detection system for recording. The transmembrane potentials propagated through cardiac cells would polarize the MEA electrodes, causing the electrode potential changes, which then was recorded as the field potential.

FIG. 30B shows representative synchronized field potential data recording of the three-cluster CM-fibroblast network. The three clusters were presented as C1, C2, and C3, respectively. The peak values of the signal were obvious and regular, and the spike amplitude was ranged ˜100 μV, which was similar to previous research on commercial MEA. The synchronized beating can also be indicated with the same beating periods of the three clusters. From comparing the waveforms of the three clusters, it is worth noting the steady peak difference between the coupled clusters. Cluster 1 is used as the reference cluster to measure the peak difference of cluster 2 and 3. The polar histogram of the peak difference shown in FIG. 30B is shown in FIG. 30C regarding the spontaneous beating as a periodic function. The peak differences were measured in the angular unit, and the height of the histogram represents the percentage of the coupled period that the peak difference is at a specific angle. The peak differences of cluster 2 and 3 compared to cluster 1 were 5° and around 67°, respectively. Such peak differences can also be observed from fluorescent videos. Ca²⁺ fluorescent videos were captured with Fluo-4 to visualize the Ca′ flux within cardiac cells as illustrated in FIG. 30D. The quantized Ca′ fluxes analyzed by pixel intensities of the fluorescent signals in the video also indicated stable peak differences among three clusters as illustrated in FIG. 30E.

To explore the coupling between rCM and fibroblasts, the impedance of the fibroblast bridge is measured in the customized impedance MEA platform. The Nyquist plot in FIG. 30F shows that the fibroblast bridge presented itself as an RC filter with a resistance of 200 kΩ and capacitance of 120 nF and provides an RC type coupling within synchronized rCM clusters.

CMs can spontaneously generate electrical signals and beat at the same frequency when coupled. This coupling is achieved by propagating electrical signals through the gap junctions of adjacent cells. Therefore, after fibroblasts grew in the bridges and connected the three rCM clusters, these three clusters would initiate the calcium exchange through the fibroblast bridges and then beat at the same pace. The stable beating peak differences between the three patterned rCM clusters, shown in both electrical and optical results, are caused by the time lag in transporting electrical signals via the fibroblast bridges.

The above results indicate that the custom-designed MEA platform can be used for studying the synchronization mechanism in the three-cluster CM-fibroblast network. The electrical data analyzed from MEA and quantized Ca²⁺ fluxes analyzed from optical videos revealed that the proliferated fibroblast bridges provide an RC type coupling and generate stable peak differences within coupled rCM clusters.

Extracellular Recording of Induced Pluripotent Stem Cell Derived CMs (iCM)

CMs derived from stem cell sources could be an indefinite source of CMs for large scale applications of bio-oscillators. However, compared to the native CMs, iCMs still display some immature signs, such as poor sarcomeric organization or different electrophysiological properties. Recently, micropatterning has been utilized to enhance the maturity of iCMs by providing topographical cues which better mimic the native environment of iCMs. The micropatterning method in accordance with some embodiments provide++ an approach to guide the coupling pathway in CM-fibroblast network which can be further used to study the influence of iCM synchronization on cell maturity by monitoring the long-term electrical activity.

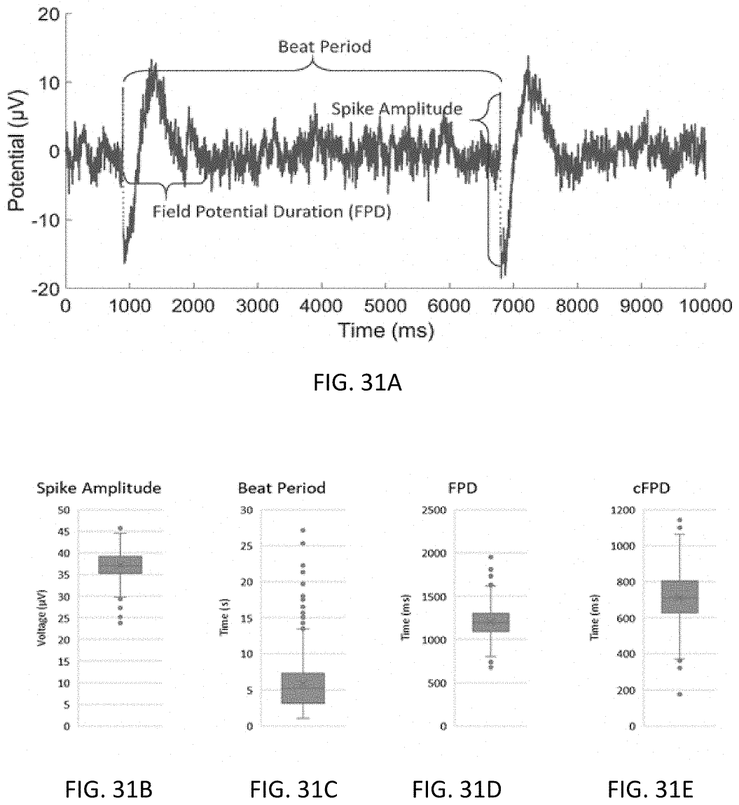

Here, the feasibility of monitoring electrophysiological properties of patterned iCMs from the MEA platform was assessed. FIG. 31A shows representative FP waveforms of cultured iCMs. Some representative electrophysiological parameters of the clustered iCMs during the 40-minute recording were also obtained, such as an average spike amplitude of 37.12±3.05 μV as illustrated in FIG. 31B, a beat period of 5.88±3.87 s as illustrated in FIG. 31C, a field potential duration (FPD) of 1203.36±172.83 ms as illustrated in FIG. 31D, and a corrected field potential correction (cFPD) of 712.48±141.58 ms as illustrated in FIG. 31E. The spike amplitudes were constant during the whole recording, while the beat period, FPD and cFPD were slightly dispersed. The spike amplitude values recorded were smaller than previously reported values, most likely due to the relatively large cell-electrode distance which results in attenuation during the signal transmission.

The micropatterning method combined with a custom-designed MEA platform provides a new approach to construct a complex CM-fibroblast network with controlled coupling pathways, which can provide more understanding of the synchronization mechanism within the cardiac tissue.

Cardiac-Muscle-Cell-Based Reprogrammable Bio-Oscillatory Networks (CARBON)

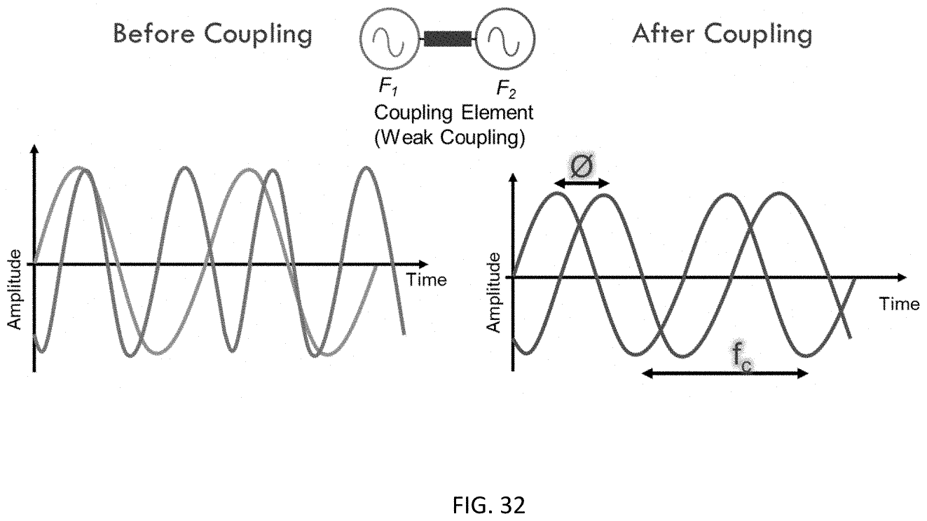

For bio-oscillators to be used in computing applications, certain system requirements need to be satisfied, for example, an array of self-sustained synchronized oscillators with a reconfigurable coupling scheme. Certain performance requirements need to be satisfied as well, including a frequency locking range, phase synchronization property, and immunity to noise. FIG. 32 illustrates beating frequencies of two bio-oscillators before coupling and after coupling. It shows that the two bio-oscillators are synchronized at the same beating frequency with a fixed phase difference after coupling.

The controlling of coupling and de-coupling of the bio-oscillatory networks is essential for building programmable networks. Some embodiments of the present inventive concept provide a new cell-based biocomputing platform Cardiac-muscle-cell-based Reprogrammable Bio-Oscillatory Network (CARBON).

This bio-oscillator network's biological computing component is the combination of electrically excitable cardiac muscle cells (CM) and non-excitable cardiac fibroblasts (CF). The coupling and de-coupling can be achieved by building and rebuilding the CF connection between CM clusters. The physical connections of CFs can be disconnected by removing CFs in the desired regions.

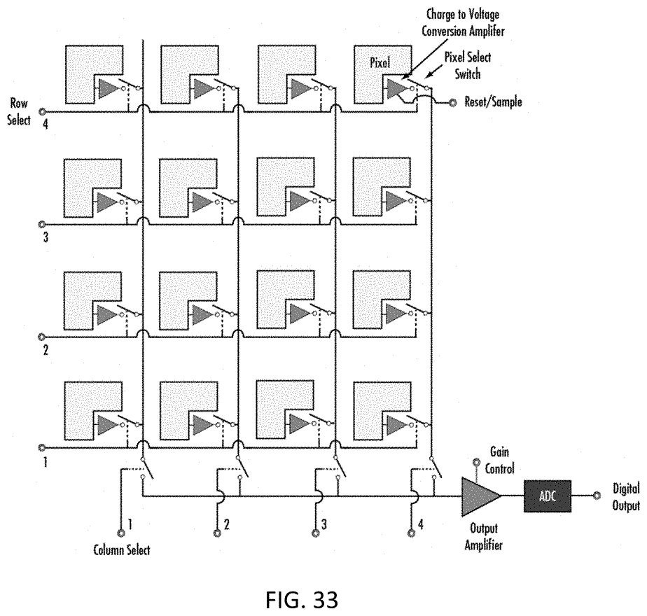

The key to a re-programmable bio-oscillatory network is the ability of selecting a specific unit (or a cluster) from a large array of bio-oscillators. As illustrated in FIG. 33, a specific input/output array of operational amplifier can select the “on” and “off” from a specific unit using the row selection and the column selection options.

The row and column selection in semiconductor circuits is easy and simple by adding multiple parallel control digital switches. Unlike the semiconductor networks, implanting the specific “switches” in a biological computing networks is challenging. The connection “wires” used for bio-oscillatory network are fibroblast cells (CFs). The coupling dynamics of different connection distances of CFs were described earlier. The formation of this connection is achieved by CF growth. This connection can be removed by relocating the formed CFs. The bridge connections can be selectively removed by adding an enzyme (e.g., trypsin) that can disconnect the CF cells from the surface. This releases the CF from the attached bottom surface, and the detached cells are washed out by the additional buffer flow. The challenging task is to accurately guide the trypsin to the specific locations, i.e., the bridges connecting two beating clusters. Therefore, a CARBON device with multiple layers of microfluidic channels is designed. Trypsin can be guided in the CARBON device to the specific connecting bridges above the CFs through attaining a laminar flow and with minimal contact to the beating cardiomyocyte clusters. Once the CFs are removed from the bridges, they can regrow in the same or in a different pattern depending on the device architecture.

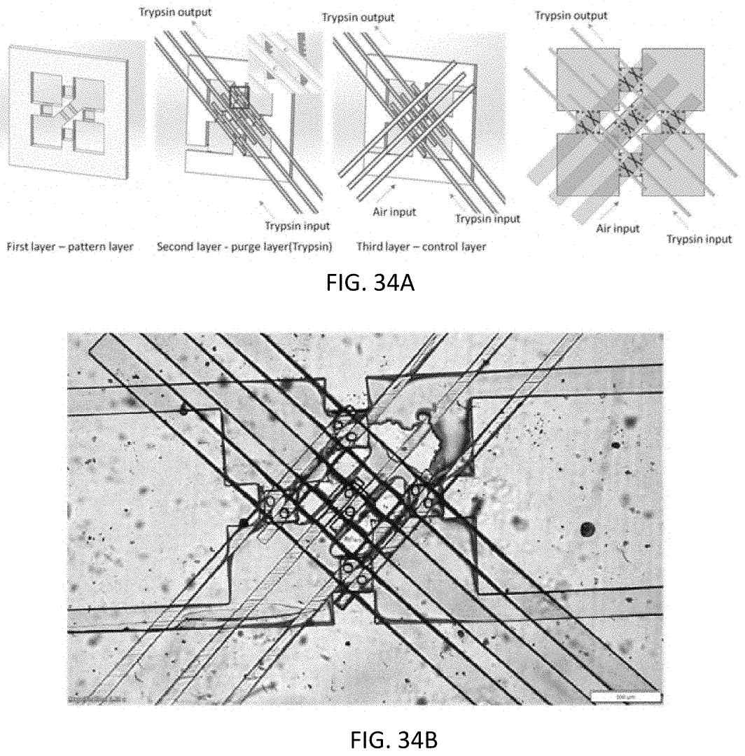

FIG. 34A illustrates a configuration of the CARBON device in accordance with some embodiments of the present inventive concept. FIG. 34B is a bright view of the CARBON device. The whole CARBON device includes three layers: the first patterning layer, the second trypsin channel layer, and the third pneumatic controlling layer. The first patterning layer defines the CM clusters. The prototype CARBON device includes 4 clusters, which can be a basic lattice unit for a larger scale network. The connection bridges of the 4-cluster network have four short connections between every two clusters, and one longer diagonal bridge connecting two clusters. The second layer guides trypsin to specific points above the bridges. The third layer is the pneumatic controlling layer. The pneumatic valve is the most common format in microfluidic controlling. With the cross pattern of the trypsin layer and pneumatic layer, any one of the 5 bridges in the 4-cluster pattern can be selected for decoupling.

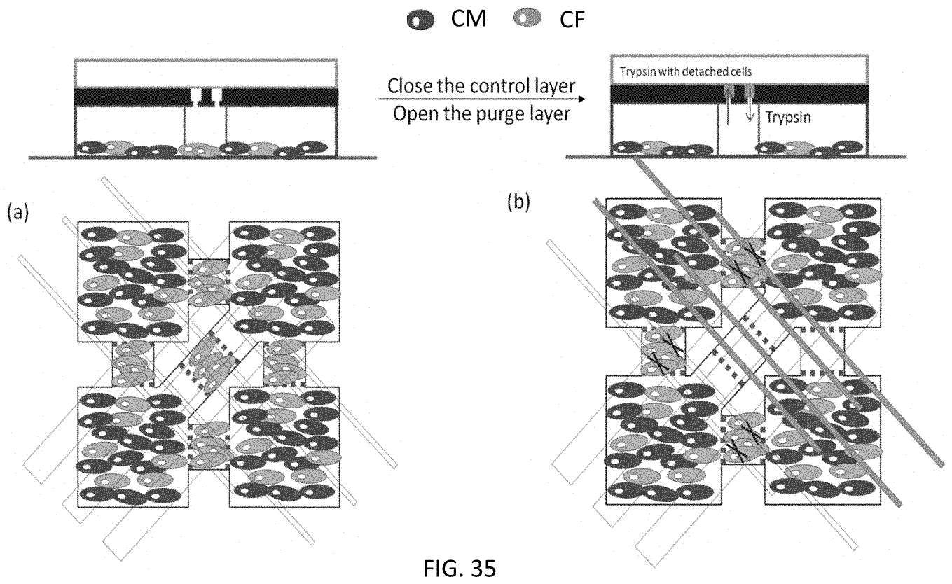

As shown in FIG. 35, the CFs are located at the bottom of the bridges. Once the trypsin openings are selected, the trypsin will be released to contact the attached CFs directly. The two openings in the trypsin channel can provide fresh trypsin and bring the trypsinized CF cells and flow through the channels.

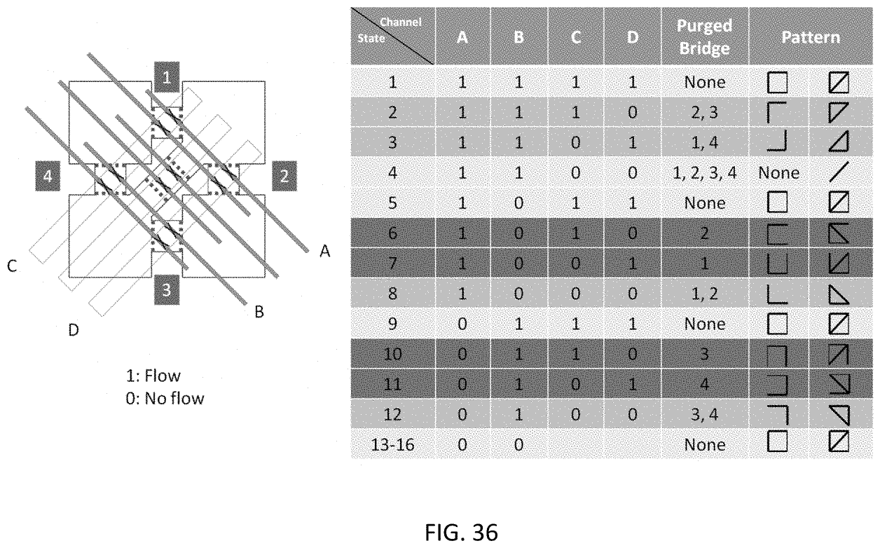

FIG. 36 provides detailed reprogramming abilities of the 4-cluster CARBON device. The trypsin channels, namely A and B, can selectively provide sufficient trypsin. The pneumatic channel C and D can selectively control the open and close between the trypsin channels and the 4-cluster pattern. The resulting patterns of the 4 clusters are determined by different combinations of the ABCD, which represent the different binary coding of each bit. Using the 4-bit coding in this 4-cluster CARBON device, 13 kinds of different patterns of bio-oscillatory networks can be generated. These networks are not only useful for vertex coloring problems in biocomputing, and this 4-cluster CARBON is also the basic lattice unit of a complete bio-computing network.

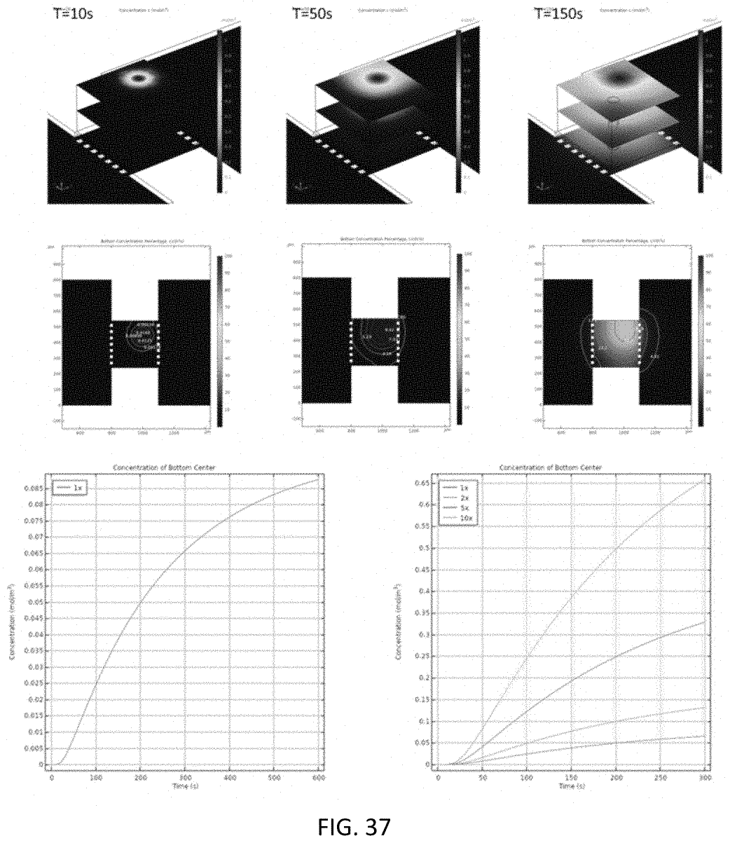

The COMSOL simulation of the trypsin diffusions as shown in FIG. 37 indicate the efficacy of the trypsinization ability of CFs in the bridges. Within 150 s, the trypsin can reach the bottom of the CM/CF patterning layer. For higher de-coupling purpose, higher concentrations of trypsin can be applied in the trypsin channel. As shown in the FIG. 37, the trypsin concentration can become higher as 0.65× at the bottom of the bridges.

Modeling of Multi-Node Bio-Oscillator Networks Using Circuit Macro Models

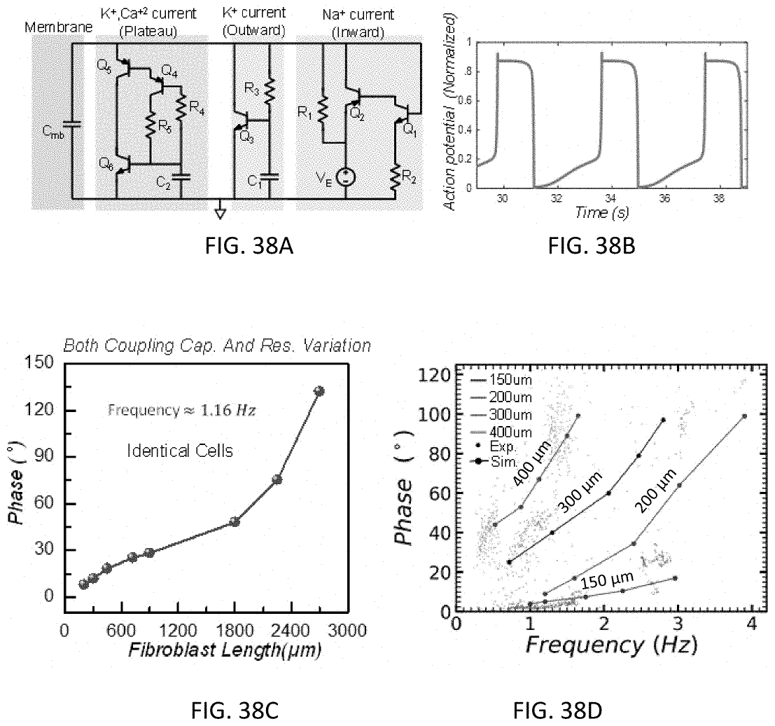

Some embodiments of the present inventive concept evaluated the computational properties of the coupled cardiac cell oscillators, which are used to guide and support the design of the cardiac cell-based oscillator networks. As mentioned earlier, a SPICE-compatible model for the cardiac cell and its subsequent integration into coupled oscillator networks can be developed as shown in FIG. 38A. The oscillator modeling considered the effect of ionic Ca2+, K+, Na+ currents, and subsequently, the experimentally observed action potential of the oscillator was replicated by adjusting the circuit parameters. FIG. 38B illustrates the action potential generated using the circuit model in FIG. 38A. FIG. 38C illustrates the phase difference (simulated) between two identical (i.e., no asymmetry between them) coupled cardiac cells as a function of fibroblast length (coupling element). FIG. 38D illustrates the simulated phase-frequency relationship of two coupled cardiac cell oscillators and its comparison to experimental data.

The electronic response of the fibroblast-based coupling elements (among the oscillators) in the network can be characterized and modeled using a parallel combination of an RC-based coupling scheme where the parameters for the components were obtained experimentally using the impedance spectroscopy. The evolution of the coupling element's response with length (relevant to scaling) was also investigated.

The physics of coupled biological oscillators can be utilized for computation. The modeling framework described above can be used to evaluate the dynamics of (fibroblast-) coupled bio-oscillators, and analyze their computational properties, particularly in solving the archetypally hard graph coloring problem. Solving the problem entails computing the minimum number of colors required to be assigned to the edges such that no two adjacent vertices (i.e., vertices that share an edge) are assigned the same color.

To solve this problem using the bio-oscillators, the graph is mapped onto the network such that each node (i.e., vertex) of the graph is represented by a CM cluster and every edge by the CF bridge. It was subsequently shown that the resulting bio-oscillator phases and their relative ordering encode the solution to the graph coloring problem—oscillators belonging to an independent set in the graph appear consecutively in the phase sequence. Each independent set can be obtained using a simple polynomial-time operation (n²) that compares the phase sequence to the adjacency matrix of the graph to identify the partition between two independent sets. Further, using standard graph theory, the nodes of a partition (e.g., independent set) can be assigned a unique color, thus, facilitating a high-quality, near-optimal solution to the problem.

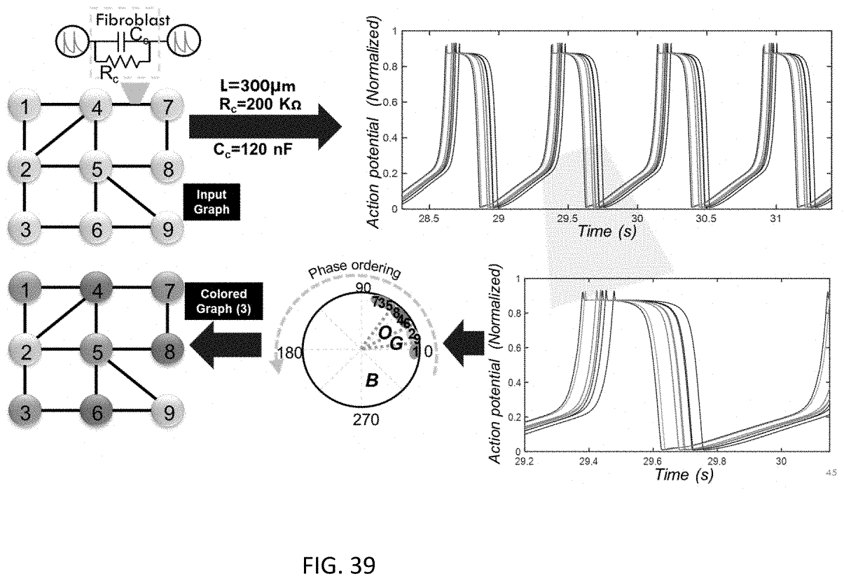

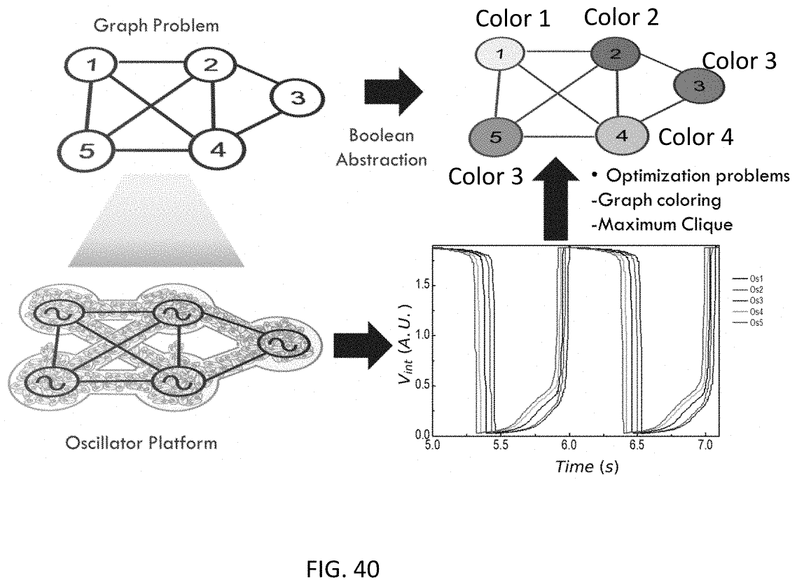

FIG. 39 provides an illustrative example to demonstrate solve the minimum vertex coloring problem in a graph using the phase dynamics of CF-coupled cardiac cell oscillators. This problem entails computing the minimum number of colors required to be assigned to the edges such that no two adjacent vertices (i.e., vertices that share an edge) are assigned the same color. To solve this problem using the bio-oscillators, the graph is mapped on to the network such that each node (e.g., vertex) of the graph is represented by a CM cluster and every edge by the CF bridge. The resulting steady state sequence of the bio-oscillators represents a unique ordering of phases where the adjacent nodes belong to an independent set. This ordering can subsequently be partitioned into independent sets using a simple polynomial time operation that compares the sequence to the adjacency matrix of the graph to identify the partition between two independent sets. Using standard graph theory, the nodes of a partition (e.g., independent set) can be assigned a unique color. For the representative graph of 9 nodes considered in FIG. 39, time domain waveforms of its topologically equivalent coupled cardiac-cell oscillator circuit can be obtained, the inset of the time domain waveforms in FIG. 39 shows a single time period for each oscillator. Then a polar phase plot is generated to show the relative phase difference amongst the oscillators. Resulting coloring solution is obtained from the phase dynamics of the oscillators. It can be observed that the bio-oscillators settle to a steady-state where the bio-oscillator phases have the following cyclic ordering: . . . 1, 9, 2, 6, 4, 8, 5, 3, 7 . . . . Subsequently, this ordering can be partitioned into 3 distinct independent sets {2,9}{6,4,8}{5,3,7,1}. Assigning each such set a color implies that a minimum of 3 colors are required to “color” the graph. Similarly, FIG. 40 illustrates solving a graph problem based on a bio-oscillator network. The 5-node graph can be mapped to a 5-node bio-oscillator network. Each node (e.g., vertex) of the graph is represented by a CM cluster and every edge by the CF bridge.

The potential of the system to be scaled to a larger number of nodes is also explored using circuit simulation in accordance with some embodiments of the present inventive concept. In such cases, the intrinsic parallelism of coupled oscillator networks is expected to yield a significant performance advantage over traditional heuristic based Boolean computing hardware. Using the oscillator and the fibroblast equivalent model simulated in Xyce (an open-source, SPICE-compatible, high-performance analog circuit simulator offered by Sandia National Labs), the ability of the system to color representative graph instances from the DIMACS data challenge is analyzed. As described earlier, the steady state phase sequence of the oscillators is used to construct the coloring solution. It can be observed that in larger graphs the solutions become sub-optimal. Therefore, a simple polynomial post-processing scheme to augment the solution is discussed in accordance with some embodiments of the present inventive concept.

In some embodiments, the ability of the system to compute the graph coloring solution in relatively large graphs (e.g., from the DIMACS implementation challenge) up to 138 nodes is considered. The dynamics of the coupled system can be simulated using Xyce. The subsequent steady-state phase dynamics of the system are analyzed. It can be observed that the phase sequence of the oscillators can be mapped to the graph coloring solution although it is sub-optimal.

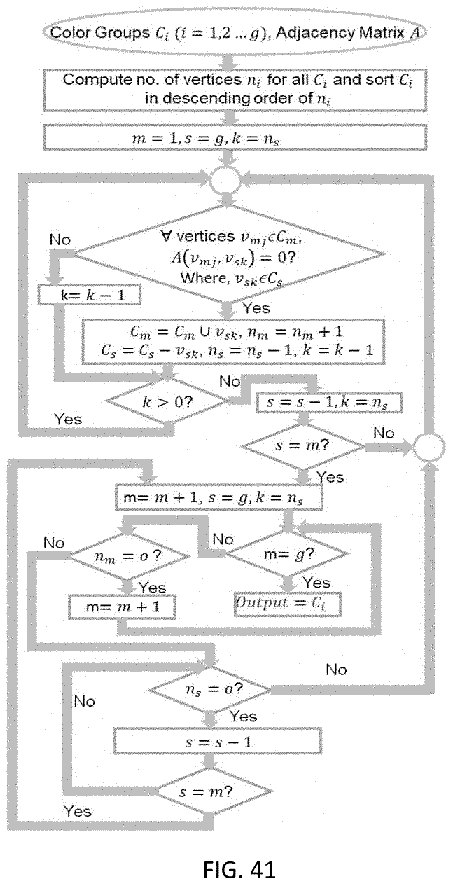

While the oscillators produced optimal (or very close to optimal) solutions in small graphs, it was observed that the deviation of the measured solution from the optimal solution increases with the size of the graph. This is not unexpected since the system has a tendency to get trapped in the local minima of the high-dimensional phase space. Therefore, a polynomial time post-processing scheme is developed using the oscillator solution as a starting point. FIG. 41 shows the flowchart for the post-processing scheme incorporated with the oscillator approach to improve the vertex coloring solution. Using the combination of oscillators and post-processing) it is observed that the oscillators produce high-quality coloring solutions that are within 2 colors of the optimal solutions (i.e., chromatic number) for the graphs from the DIMACS dataset. Graph instances from the DIMACS database can be evaluated using the coupled oscillators without post-processing and with postprocessing to demonstrate that the proposed post-processing scheme can improve the graph coloring solution obtained from the oscillators.

The heuristic post-processing algorithm illustrated by the flow-chart in FIG. 41 improves the solution without a significant penalty to the computation time. The polynomial-time scheme proceeds by sorting the color groups (obtained from the oscillators) in the descending order of their size (i.e., number of vertices). Subsequently starting from the lowest color group, the algorithm checks the connectivity of the vertices with the vertices in the higher color groups is checked and moves them if it is valid (i.e., there exists no common edges). By following this scheme, the smaller color groups are distributed to the larger groups which subsequently improves the solution.

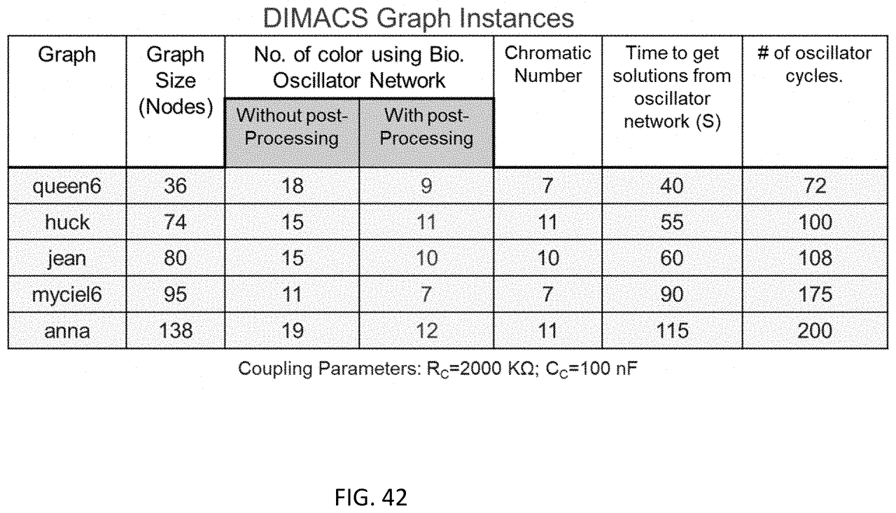

FIG. 42 provides coloring solutions computed by the oscillators for different graphs from the DIMACS implementation challenge. Coupled cardiac cell oscillator network exhibits promising results to solve vertex coloring problems for larger graphs. Coupled oscillators along with the post-processing can provide optimal and near-optimal vertex coloring solution.

This framework can be extended to solving even larger graphs. The preliminary analysis (initially performed with CMOS-based oscillators) of the computational performance of this “hybrid” approach shows a significant improvement (>100×) in the time-to-compute solution.

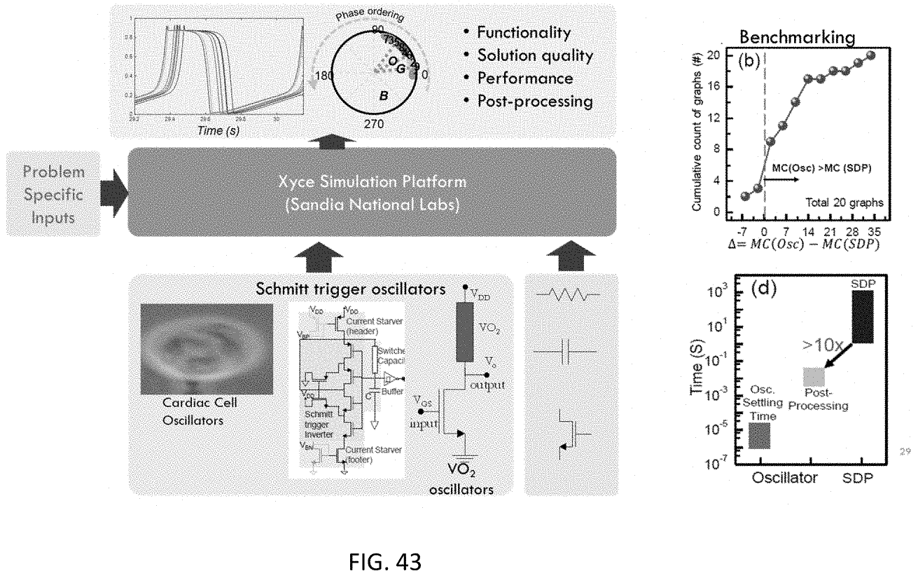

The dynamics of large graph networks with coupled oscillators can be evaluated over a Xyce platform as shown in FIG. 43, without post-processing and with post-processing.

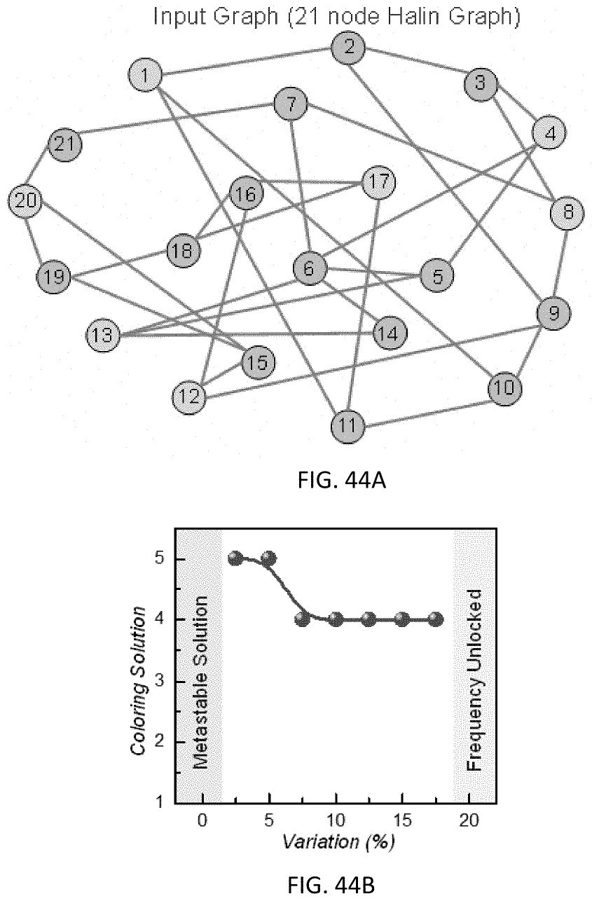

Some embodiments of the present inventive concept provide a systematic study on how variation in the devices affects the computational performance of the oscillators as shown in FIG. 44. FIG. 44A illustrates a 21-node Halin graph network. There are three independent sets, {1, 4, 8, 12, 13, 17, 20}, {2, 6, 10, 16, 19, 21}, and {3, 5, 7, 9, 11, 14, 15, 18}. Assigning each such set a color implies that a minimum of 3 colors are required to “color” the graph. FIG. 44B illustrates its oscillator generated coloring solution as a function of device-to-device variation. It indicates that some level of variation (unavoidable in a physical system) may be desirable since it prevents the system from getting stuck in metastable states (e.g., all oscillators have the same frequency and are trivially locked in phase). However, the variation must be small enough else it will prevent the system from getting frequency locked. Future work will investigate how these effects evolve with graph size, edge density, etc.

Some embodiments of the present inventive concept demonstrate the feasibility of coupled oscillator networks made of living cardiac muscle cells, or bio-oscillators, as a physical biocomputational substrate for solving constrained optimization problems like vertex coloring of graphs. While current approaches in bio-computation have so far been successful in archival data storage, they still fail to compete with silicon-based digital electronics in terms of parallel data processing. Data processing through genetic manipulations requires timescales that are much longer than those that are required for majority of computational tasks and input/output strategies are not compatible with conventional Silicon-based technologies. Furthermore, in such systems, processing and communication are mostly implemented by altering molecules which are irreversible and not programable/reconfigurable once built. Therefore, there is a big gap between current biocomputing approaches and future high speed, large-scale data processing and transmission requirements. Currently, there is no cell-based biocomputing circuitry that operates as cell-scale networks and process information carried by electrical signals. The results in accordance with some embodiments usher in a new paradigm to the emerging field of biocomputing. In contrast to the conventional approach of creating bio-circuits using genetic manipulation of the cell as well as introducing chemicals and biomolecules, some embodiments show that cell-scale networks and their natural ability to communicate with each and synchronize to a state with unique phase pattern, can be used as a computational primitive for efficiently solving computationally hard problems.

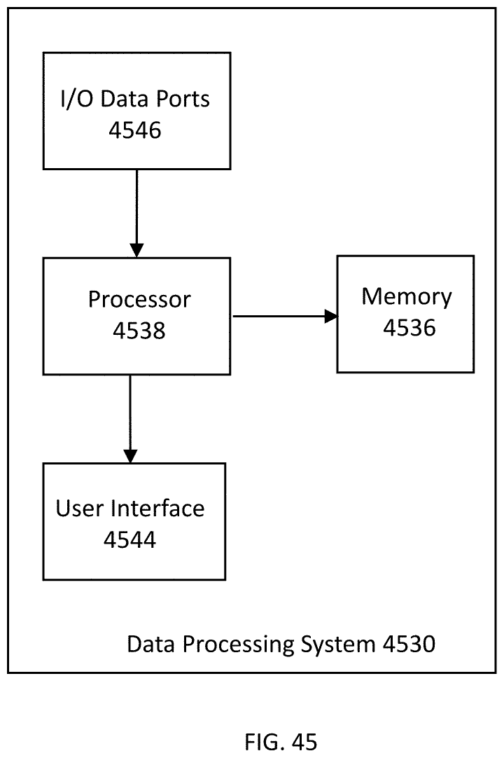

As is clear from the embodiments discussed above, some aspects of the present inventive concept may be implemented by a data processing system. The data processing system may be included at any module of the system without departing from the scope of the preset inventive concept. Exemplary embodiments of a data processing system 4530 configured in accordance with embodiments of the present inventive concept will be discussed with respect to FIG. 45. The data processing system 4530 may include a user interface 4544, including, for example, input device(s) such as a keyboard or keypad, a display, a speaker and/or microphone, and a memory 4536 that communicate with a processor 4538. The data processing system 930 may further include I/O data port(s) 4546 that also communicates with the processor 4538. The I/O data ports 4546 can be used to transfer information between the data processing system 4530 and another computer system or a network using, for example, an Internet Protocol (IP) connection. These components may be conventional components such as those used in many conventional data processing systems, which may be configured to operate as described herein.

In the drawings and specification, there have been disclosed exemplary embodiments of the inventive concept. However, many variations and modifications can be made to these embodiments without substantially departing from the principles of the present inventive concept. Accordingly, although specific terms are used, they are used in a generic and descriptive sense only and not for purposes of limitation, the scope of the inventive concept being defined by the following claims.

That which is claimed is:

1. A coupled bio-oscillating material, comprising:
at least two cardiac muscle (CM) cell clusters and at least one cardiac fibroblast (CF) cell bridge on a substrate;
wherein the at least one CF cell bridge provides electrical conduction between the at least two CM cell clusters; and
wherein the at least two CM cell clusters oscillate and synchronize at a unique phase ordering between the at least two CM cell clusters.

2. The coupled bio-oscillating material of claim 1, wherein the substrate is embedded with a microelectrode array (MEA).

3. The coupled bio-oscillating material of claim 2, wherein the MEA is configured to measure a field potential of the at least two CM cell clusters.

4. The coupled bio-oscillating material of claim 1, wherein the at least one CF cell bridge is equivalent to a Resistor-Capacitor (RC) filter.

5. The coupled bio-oscillating material of claim 1, wherein the at least two CM cell clusters synchronize at a frequency in a range from 0.01 Hz to 10 Hz.

6. The coupled bio-oscillating material of claim 5, wherein the at least two CM cell clusters oscillate initially at frequencies different from the synchronized frequency.

7. A coupled bio-oscillator network, comprising:
at least two biological oscillators, and at least one biological coupling element;
wherein the at least one biological coupling element connects the at least two biological oscillators; and
wherein the at least two biological oscillators are synchronized with a unique phase ordering between the at least two biological oscillators.

8. The coupled bio-oscillator network of claim 7, wherein the at least one biological coupling element is configured to connect with the at least two biological oscillators electrically, mechanically, or optically.

9. The coupled bio-oscillator network of claim 7, wherein the at least one biological coupling element comprises a plurality of cardiac fibroblast (CF) cells.

10. The coupled bio-oscillator network of claim 7, wherein the at least two biological oscillators comprise a plurality of cardiac muscle (CM) cells.

11. A method of creating a coupled bio-oscillator network, comprising:
preplating a mixture of cardiac muscle (CM) cells and cardiac fibroblast (CF) cells in culture;
fabricating a biocompatible stencil for patterning the CM cells and the CF cells on a substrate;
providing at least one biocompatible blocker on the substrate to block at least one portion of the substrate;
treating an unblocked portion of the substrate with cell attachment agent to enable cell attachment on the substrate;
coating the unblocked portion of the substrate with the mixture of CM cells and CF cells to seed at least two CM-CF cell clusters; and
removing the at least one biocompatible blocker to enable CF cells in the at least two CM-CF cell clusters to proliferate and fill at least one gap between the at least two CM-CF cell clusters and couple the at least two CM-CF cell clusters, wherein the at least two CM-CF cell clusters are synchronized with a unique phase ordering between the at least two CM-CF cell clusters.

12. The method of creating a coupled bio-oscillator network of claim 11, wherein a ratio between the CM cells and the CF cells in the mixture is about 7:3 after preplating for about 2 hours.

13. The method of creating a coupled bio-oscillator network of claim 11, wherein the cell attachment agent comprises fibronectin, and wherein the fibronectin is diluted in a buffer solution.

14. The method of creating a coupled bio-oscillator network of claim 11, further comprising treating the unblocked portion of the substrate with the cell attachment agent in a 37° C. incubator for about 30 minutes.

15. The method of creating a coupled bio-oscillator network of claim 11, wherein the CM cells in the at least two CM-CF clusters start to oscillate after about 1.5˜2 days of culture.

16. The method of creating a coupled bio-oscillator network of claim 11, wherein a width of the at least one biocompatible blocker is between about 1 μm and lcm.

17. The method of creating a coupled bio-oscillator network of claim 11, further comprising measuring and recording a field potential (FP) of the at least two CM-CF clusters with a microelectrode array (MEA).

18. The method of creating a coupled bio-oscillator network of claim 17, further comprising extracting a frequency and a phase of an oscillation of the at least two CM-CF clusters based on Fourier transform and peak detection of the FP of the at least two CM-CF clusters.

19. The method of creating a coupled bio-oscillator network of claim 11, further comprising extracting a frequency and a phase of an oscillation of the at least two CM-CF clusters based on microscopy imaging.

20. The method of creating a coupled bio-oscillator network of claim 11, wherein the biocompatible stencil comprises polydimethylsiloxane (PDMS).

21. The method of creating a coupled bio-oscillator network of claim 11, wherein the biocompatible stencil is about 140 μm thick.

22. The method of creating a coupled bio-oscillator network of claim 11, wherein the at least one biocompatible blocker comprises PDMS.

23. The method of creating a coupled bio-oscillator network of claim 11, wherein the CM cells are derived from stem cell sources.

24. A re-programmable bio-oscillatory network, comprising:
a patterning layer comprising at least two biological oscillators and at least one biological coupling element, wherein the at least one biological coupling element connects the at least two biological oscillators, wherein the at least two biological oscillators are synchronized with a unique phase ordering between the at least two biological oscillators;
an enzyme channeling layer comprising at least one enzyme channel on top of the at least one biological coupling element, wherein the at least one enzyme channel guides an enzyme fluid to a specific point on top of each of the at least one biological coupling element; and
a pneumatic controlling layer comprising at least one pneumatic channel crossing the at least one enzyme channel, wherein the at least one pneumatic channel guides an air flow to selectively control a flow of enzyme fluid in each of the at least one enzyme channel.

25. The re-programmable bio-oscillatory network of claim 24, wherein the enzyme fluid comprises Trypsin.

26. The re-programmable bio-oscillatory network of claim 24, wherein the at least one enzyme channel comprises an opening at the specific point on top of each of the at least one biological coupling element.

27. The re-programmable bio-oscillatory network of claim 24, wherein the enzyme fluid is operable to disconnect the at least one coupling element from the patterning layer at the specific point.

28. A method of collective computing by a coupled bio-oscillator network, comprising:
providing a graph representing a minimum vertex coloring problem;
providing a coupled bio-oscillator network mapped with the graph, wherein the coupled bio-oscillator network comprises a plurality of cardiac muscle (CM) cell clusters and a plurality of cardiac fibroblast (CF) cell bridges, wherein the plurality of CM cell clusters are coupled by the plurality of CF cell bridges, wherein each of the plurality of CM cell clusters is mapped to a node of the graph and each of the plurality of CF cell bridges is mapped to an edge of the graph, wherein the plurality of CM cell clusters oscillates and synchronizes at a steady-state sequence;
partitioning the plurality of CM cell clusters into independent sets by comparing the steady-state sequence to an adjacency matrix of the graph; and
assigning a unique color to each of the independent sets.

29. The method of collective computing by a coupled bio-oscillator network of claim 28, further comprising sorting the independent sets in a descending order by size.

30. The method of collective computing by a coupled bio-oscillator network of claim 29, further comprising distributing a smaller independent set to a larger independent set if the smaller independent set and the larger independent set have no common edges.
